(19) United States
(12) Patent Application Publication
(10) Pub. No.: US 2025/0221060 A1
(43) Pub. Date: Jul. 3, 2025

(54) SEMICONDUCTOR LIGHT-RECEIVING DEVICE

(71) Applicant: Mitsubishi Electric Corporation, Tokyo (JP)

(72) Inventors: Eitaro ISHIMURA, Tokyo (JP); Harunaka YAMAGUCHI, Tokyo (JP); Akitsugu NIWA, Tokyo (JP); Ryota TAKEMURA, Tokyo (JP)

(73) Assignee: Mitsubishi Electric Corporation, Tokyo (JP)

(21) Appl. No.: 18/867,215

(22) PCT Filed: Jul. 19, 2022
(86) PCT No.: PCT/JP2022/027974

§ 371 Date: Nov. 19, 2024

(51) Int. Cl. H10F 30/225; H10F 77/124; H10F 77/16

(52) U.S. Cl. CPC H10F 30/225; H10F 77/1248; H10F 77/16

(57) ABSTRACT

A semiconductor light-receiving device (100) of the present disclosure includes: a semiconductor substrate (1); an n-type buffer layer (2) formed above the semiconductor substrate (1); a multiplication layer (3) formed above the n-type buffer layer (2); a p-type electric field control layer (4) formed above the multiplication layer (3); and a light absorption layer (5) formed above the p-type electric field control layer (4), wherein any one, any two, or three of the n-type buffer layer (2), the multiplication layer (3), and the p-type electric field control layer (4) are composed of a digital alloy structure.

### TECHNICAL FIELD

The present disclosure relates to a semiconductor light-receiving device.

### BACKGROUND ART

Communication networks for exchanging digital information and data centers for storing and processing the digital information have been developed remarkably with the development of digital transformation utilizing digital information. Optical communications are used for communication networks and intra-data center communications, which has seen remarkable progress in recent years in achieving higher speeds and greater capacity. An avalanche photodiode (APD) capable of high light-receiving sensitivity is used on the receiving side of optical communications.

APDs are roughly classified into two types: a surface-incident type APD in which light is incident from the upper surface direction of a wafer and a waveguide type APD in which light is incident from the end surface direction of a chip. The surface-incident type APD has a light-receiving section with a diameter of about 10 to 100 μm and is easy to couple light to an optical fiber. However, in order to increase light-receiving sensitivity, a light absorption layer needs to be as thick as several microns, which increases the time for electrons and holes to travel through the light absorption layer, resulting in poor high-speed response. In contrast, the waveguide type APD has a structure that absorbs light while propagating light incident from the chip end surface into a waveguide-shaped light absorption layer, and thus, even when the light absorption layer is thinned to 1 μm or less, high light-receiving sensitivity can be achieved.

As described above, the waveguide type APD is the most important light-receiving device for high-speed communications at 25 Gbit/sec or higher because of their excellent high-speed response. In recent years, waveguide type APDs have been required to achieve even higher speeds and light-receiving sensitivity. To achieve even higher light-receiving sensitivity, it is necessary to efficiently couple incident light into an optical waveguide of APDs.

### CITATION LIST

### Patent Document

Patent Document 1: Japanese Laid-Open Patent Publication No. 2007-311455

### Non-Patent Document

Non-Patent Document 1: Jiyuan Zheng et al., “Digital Alloy InAlAs Avalanche Photodiodes”, JOURNAL OF LIGHTWAVE TECHNOLOGY, VOL. 36, NO. 17, September 1, pp. 3580 to 3585, 2018

### SUMMARY OF THE INVENTION

### Problem to be Solved by the Invention

APDs are mainly composed of a light absorption layer (InGaAs), an electric field control layer (InP or InAlAs), and a multiplication layer (InP or InAlAs). A high electric field of about 800 kV/cm is applied to the multiplication layer to multiply (ionize) holes and electrons which are generated in the light absorption layer. The electric field control layer functions to weaken the electric field so that the high electric field of the multiplication layer is not applied to the light absorption layer.

In general, a compound semiconductor such as InAlAs or InAlGaAs having a refractive index n higher than that of InP, which is a semiconductor material constituting a substrate and a cladding layer, is used for the electric field control layer and the multiplication layer of the waveguide type APD. In APDs, as the difference in ionization rate between holes and electrons increases, excess noise generated during multiplication decreases, and thus light-receiving sensitivity increases. InAlAs has a larger difference in ionization rate between electrons and holes than InP. Not that, in InP, the ionization rate of holes is higher than the ionization rate of electrons, that is, the ionization rate of holes is about twice the ionization rate of electrons. In contrast, in InAlAs, the ionization rate of electrons is higher than the ionization rate of holes, that is, the ionization rate of electrons is about five times the ionization rate of holes.

Consequently, since light-receiving sensitivity is higher when InAlAs is applied as the multiplication layer of APDs than when InP is applied, InAlAs is more preferable than InP for the multiplication layer of waveguide type APDs.

Among the light absorption layer (InGaAs), the electric field control layer (InAlAs), the multiplication layer (InAlAs), the buffer layer (InAlAs), and the cladding layer (InP) positioned in the vertical direction, which constitute waveguide type APDs, the light absorption layer has the highest refractive index n, and the electric field control layer, the multiplication layer, and the buffer layer have the second highest refractive index n. When light propagates through a waveguide, the light tends to be confined in a layer having a higher refractive index n. That is, a large amount of the light is confined in the light absorption layer having the highest refractive index n, but the light is also confined in the electric field control layer, the multiplication layer, and the buffer layer having the second highest refractive index n. Thus, the optical distribution becomes asymmetric in the vertical direction. As a result, there is a problem that the amount of the light confined in the light absorption layer (light confinement rate) decreases. In the above description, the vertical direction is the direction perpendicular to the substrate surface, and the direction away from the substrate starting from the light absorption layer is the upward direction, and the direction approaching the substrate is the downward direction.

The semiconductor light-receiving device described in Patent Document 1 suggests the idea of sandwiching the light absorption layer between InAlGaAs (optical confinement layers) with a high refractive index n to increase the light confinement ratio. However, the extra time required for electrons and holes to travel through the optical confinement layers results in a deterioration of high-speed response. Furthermore, a layer having a high refractive index n such as InAlGaAs or InGaAsP has low thermal conductivity and thus deteriorates in heat dissipation, which may degrade semiconductor light-receiving devices when input intensity of light is high.

The present disclosure has been made to solve the above problem, and an object of the present disclosure is to provide a semiconductor light-receiving device having high light-receiving sensitivity and excellent high-speed response.

### Means to Solve the Problem

A semiconductor light-receiving device according to the present disclosure includes: a semiconductor substrate; an n-type buffer layer formed above the semiconductor substrate; a multiplication layer formed above the n-type buffer layer; a p-type electric field control layer formed above the multiplication layer; and a light absorption layer formed above the p-type electric field control layer; wherein any one, any two, or three of the n-type buffer layer, the multiplication layer, and the p-type electric field control layer are composed of a digital alloy structure.

### Effect of the Invention

In the optical semiconductor light-receiving device according to the present disclosure, any one, any two, or three of the n-type buffer layer, the multiplication layer, and the p-type electric field control layer are composed of the digital alloy structure, thus providing an effect of achieving a semiconductor light-receiving device having high light-receiving sensitivity and excellent high-speed response.

### BRIEF DESCRIPTION OF THE DRAWINGS

FIG. 1 is a cross-sectional view showing the structure of a semiconductor light-receiving device according to Embodiment 1;

FIG. 2 is a cross-sectional view showing the structure of a semiconductor light-receiving device according to a comparative example;

FIG. 3 is a graph showing the relationship between refractive index n and wavelength in DA-InAlAs, bulk-crystal InAlAs, and InP;

FIG. 4 is a cross-sectional view showing the structure of a semiconductor light-receiving device according to Embodiment 2;

FIG. 5 is a cross-sectional view showing the structure of a semiconductor light-receiving device according to Embodiment 3;

FIG. 6 is a cross-sectional view showing the structure of a semiconductor light-receiving device according to Embodiment 3;

FIG. 7 is a cross-sectional view showing the structure of a semiconductor light-receiving device according to Embodiment 4;

FIG. 8 is a cross-sectional view showing the structure of a semiconductor light-receiving device according to Modification 1 of Embodiment 4;

FIG. 9 is a cross-sectional view showing the structure of a semiconductor light-receiving device according to Modification 2 of Embodiment 4;

FIG. 10 is a cross-sectional view showing the structure of a semiconductor light-receiving device according to Modification 3 of Embodiment 4;

FIG. 11 is a cross-sectional view showing the structure of a semiconductor light-receiving device according to Embodiment 5;

FIG. 12 is a cross-sectional view showing the structure of a semiconductor light-receiving device according to Modification 1 of Embodiment 5;

FIG. 13 is a cross-sectional view showing the structure of a semiconductor light-receiving device according to Modification 2 of Embodiment 5;

FIG. 14 is a cross-sectional view showing the structure of a semiconductor light-receiving device according to Embodiment 6;

FIG. 15 is a cross-sectional view showing the structure of a semiconductor light-receiving device according to Modification 1 of Embodiment 6.

### DESCRIPTION OF EMBODIMENTS

### Embodiment 1

### <Structure of Semiconductor Light-Receiving Device According to Embodiment 1>

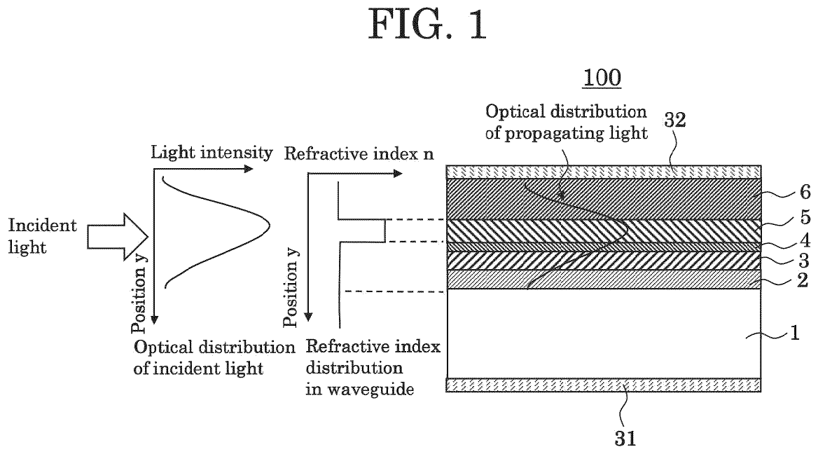

FIG. 1 is a cross-sectional view showing the structure of a semiconductor light-receiving device 100 according to Embodiment 1. A waveguide type APD is given as an example of the semiconductor light-receiving device 100 according to Embodiment 1.

The semiconductor light-receiving device 100 according to Embodiment 1 includes: an n-type InAlAs buffer layer 2 having a carrier concentration of 1×10¹⁸ to 5×10¹⁸ cm⁻³ and a total thickness of 0.1 to 1.0 μm and composed of a digital alloy structure in which n-type AlAs layers (for example, a thickness of two monolayers, about 0.5 nm) and n-type InAs layers (for example, a thickness of two monolayers, about 0.5 nm) are alternately stacked a plurality of times (hereinafter referred to as “n-type DA-InAlAs buffer layer 2”); an i-type InAlAs multiplication layer 3 having a carrier concentration of 5×10¹⁷ cm⁻³ or less and a total thickness of 0.05 to 0.4 μm and composed of a digital alloy structure in which i-type AlAs layers (for example, a thickness of two monolayers, about 0.5 nm) and i-type InAs layers (for example, a thickness of two monolayers, about 0.5 nm) are alternately stacked a plurality of times (hereinafter referred to as “i-type DA-InAlAs multiplication layer 3”); a p-type InAlAs electric field control layer 4 having a carrier concentration of 1×10¹⁶ to 1×10¹⁸ cm⁻³ and a total thickness of 10 to 100 nm and composed of a digital alloy structure in which p-type AlAs layers (for example, a thickness of two monolayers, about 0.5 nm) and p-type InAs layers (for example, a thickness of two monolayers, about 0.5 nm) are alternately stacked a plurality of times (hereinafter referred to as “p-type DA-InAlAs electric field control layer 4”); an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

Regarding the digital alloy structure, for example, the digital alloy structure in which AlAs layers and InAs layers are alternately stacked a plurality of times is hereinafter referred to as DA-InAlAs.

A transition layer having a thickness of 0.1 μm or less and made of a compound semiconductor material such as InAlGaAs or InGaAsP may be provided between the p-type DA-InAlAs electric field control layer 4 and the i-type InGaAs light absorption layer 5. InAlGaAs or InGaAsP constituting the transition layer has a bandgap energy value intermediate between the bandgap energy of InAlAs constituting the p-type DA-InAlAs electric field control layer 4 and the bandgap energy of InGaAs constituting the i-type InGaAs light absorption layer 5. Providing such a transition layer enables to prevent the accumulation of electrons and holes at the heterojunction interface.

For the same purpose as the above-mentioned transition layer, a transition layer having a thickness of 0.1 μm or less and made of a compound semiconductor material such as InAlGaAs or InGaAsP may be provided between the i-type InGaAs light absorption layer 5 and the p-type InP cladding layer 6. InAlGaAs or InGaAsP constituting the transition layer has a bandgap energy value intermediate between the bandgap energy value of InGaAs constituting i-type InGaAs light absorption layer 5 and the bandgap energy value of InP constituting the p-type InP cladding layer 6. Providing such a transition layer enables to prevent the accumulation of electrons and holes at the heterojunction interface.

In the semiconductor light-receiving device 100 according to Embodiment 1, all of the n-type DA-InAlAs buffer layer 2, the i-type DA-InAlAs multiplication layer 3, and the p-type DA-InAlAs electric field control layer 4 are composed of DA-InAlAs, but a certain degree of effect can be obtained even when the DA-InAlAs is applied to only some of the layers. For example, n-type bulk-crystal InP or n-type bulk-crystal InAlAs may be used as the n-type buffer layer. Conversely, it is also possible to use bulk-crystal InAlAs, as the multiplication layer or the electric field control layer, and apply the DA-InAlAs only to the n-type buffer layer.

The semiconductor light-receiving device 100 according to Embodiment 1 has a structure in which AlAs layers (a thickness of two monolayers, about 0.5 nm) and InAs layers (a thickness of two monolayers, about 0.5 nm) are alternately stacked a plurality of times. It is considered that when the thickness of each of the AlAs layer and the InAs layer may be in the range from one monolayer to ten monolayers, respectively, the refractive index decreases due to the regularity of the atomic layer arrangement peculiar to digital alloys. However, when the thickness of each of the AlAs layer and the InAs layer is one monolayer, the period is too small to be close to a random atomic layer arrangement, and thus the degree of decrease in the refractive index n is small. When the thickness of each of the AlAs layer and the InAs layer exceeds eight monolayers, band discontinuities between each layer begin to occur, and thus hole transport is affected, resulting in a decrease in response speed, so that the thickness of each of the AlAs layer and the InAs layer is preferably two monolayers or more and eight monolayers or less. Furthermore, when the thickness of each layer exceeds six monolayers, each layer functions as a quantum well and thus unnecessary optical absorption occurs, so that the thickness between two monolayers and six monolayers for the AlAs layer and the InAs layer, respectively, is preferable.

That is, the thickness of the AlAs layer in DA-InAlAs is preferably in the range of N times (2≤N≤6) the thickness of the monolayer, and the thickness of the InAs layer in DA-InAlAs is preferably in the range of M times (2≤M≤6) the thickness of the monolayer.

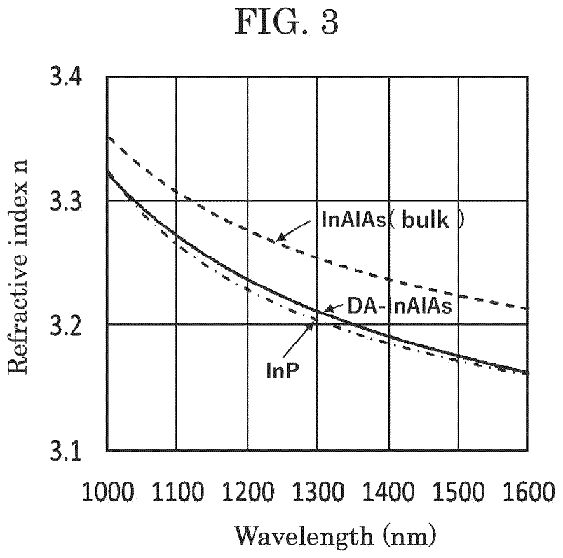

Furthermore, when the thickness of each of the AlAs layer and the InAs layer is two monolayers or more and four monolayers or less (2≤M, N≤4), the thickness of each layer is thin and has a margin with respect to the critical thickness from the viewpoint of crystal growth, and thus, crystal defects caused by the lattice mismatch degree of each layer are less likely to occur. Ideally, the thickness of two monolayers, which has the most margin for the critical thickness, is preferable. FIG. 3 is a graph showing the relationship between the refractive index n and the wavelength in DA-InAlAs (the thickness of each of the AlAs layer and the InAs layer is two monolayers), bulk-crystal InAlAs, and InP. Ideally, the thickness of each layer of DA-InAlAs is set to be two monolayers, so that the decrease in the refractive index n becomes the maximum. As a result, as shown in FIG. 3, the refractive index n of DA-InAlAs is almost equal to the refractive index n of InP. That is, it is understood that the refractive index n of DA-InAlAs is remarkably lower than the refractive index n of bulk-crystal InAlAs. The term “almost equal” means that the difference Δn between the refractive index n of DA-InAlAs and the refractive index n of InP is preferably in the range of 0≤Δn≤0.02.

A digital alloy structure other than DA-InAlAs, that is, DA-InAlGaAs in which InAlzGa(1-z)As (a thickness is two monolayers or more and six monolayers or less, Al composition ratio z) and InAlz′Ga(1-z′)As (a thickness is two monolayers or more and six monolayers or less, Al composition ratio z′) are alternately crystal-grown a plurality of times can be similarly applied to each layer such as the multiplication layer. Furthermore, a compound semiconductor material system with Sb added, for example, a digital alloy structure composed of a quaternary compound semiconductor material such as InAlAsSb, can also be applied to each layer such as the multiplication layer in the same manner.

In addition, for the i-type DA-InAlAs multiplication layer 3, the number of times of stacking in the case where the thickness of the i-type DA-InAlAs multiplication layer 3 is 0.05 to 0.4 μm and two monolayers of AlAs layers (0.5 nm) and two monolayers of InAs layers (0.5 nm) are alternately stacked a plurality of times therein is preferably in a range of 100 times to 800 times.

In the device structure of APDs, when the refractive index n of the cladding layer (InP) in the vertical direction with respect to the waveguide is almost the same as the refractive index n of the electric field control layer, the multiplication layer, and the n-type buffer layer, and the refractive index n of the light absorption layer only is made higher, the optical distribution is concentrated on the light absorption layer, that is, the light confinement rate in the light absorption layer can be increased.

However, when the multiplication layer is made of InP that is the same compound semiconductor material as the cladding layers in the upper and lower directions thereof, there is a problem that noise increases as described above. The inventors have studied intensively to solve such problems and found for the first time that replacing InAlAs, which is a bulk crystal of a ternary compound semiconductor, with a digital alloy structure reduces the refractive index n of the multiplication layer, and thus the refractive index n thereof is almost the same as that of InP, which is a binary compound semiconductor.

In the following description, a digital alloy structure made of InAlAs will be described as a specific example of the digital alloy structure. Conventional InAlAs has a random arrangement of Al and In atoms while maintaining a certain compositional ratio of Al, In, and As, and is called a bulk crystal or a random alloy structure.

Meanwhile, a structure in which AlAs and InAs, which are binary compound semiconductors, are alternately stacked a plurality of times to form InAlAs with a thickness of several monolayers (the thickness of each layer is two monolayers or more and six monolayers or less: the thickness of each layer is 0.5 to 1.8 nm) is called a digital alloy, a pseudoalloy, or the like. Digital alloys are described in Non-Patent Document 1. Pseudoalloys are also described in U.S. Pat. No. 6,326,650.

As described above, digital alloy structures are composed of multiple kinds of semiconductors with different physical properties stacked with each layer thickness of several atomic layers level, with each constituent atom artificially arranged. Similar structures to digital alloy structures include stacked structures such as multiple quantum well (MQW) structures or superlattice (SL) structures. However, such structures are essentially different from digital alloy structures in that constituent atoms are randomly arranged in each layer while maintaining a certain compositional ratio.

In a typical multiple quantum well structure or a typical superlattice structure, each layer thereof has its own band structure. In contrast, digital alloy structures are periodically stacked structures in which several monolayers are alternately stacked, and thus, digital alloy structures do not exhibit the properties of each of the AlAs layer and the InAs layer, and have a band structure close to bulk-crystal InAlAs corresponding to an averaged composition ratio. The refractive index n is expected to be lower in digital alloy structures than in bulk crystals because each constituent atom of digital alloy structures is regularly stacked and retains an atomic periodicity that is not present in random alloy structures.

In addition to the binary compound semiconductor AlAs and InAs stacked structure described above, the digital alloy structure may be formed of InGaAs in which InAs and GaAs, which are also binary compound semiconductors, are alternately stacked, InAlGaAs in which InAlAs and InGaAs, which are ternary compound semiconductors, are alternately stacked with a thickness of several monolayers, or InAlGaAs in which InAlzGa(1-z)As and InAlz′Ga(1-z′)As, which are quaternary compound semiconductors, are alternately stacked with a thickness of several monolayers.

InAlGaAs in which AlAs, which is a binary compound semiconductors, and InzGa(1-z)As, which is a ternary compound semiconductor, are alternately stacked is applicable to the digital alloy structure. A stacked structure in which InzGa(1-z)As, which is a ternary compound semiconductor, and InAlz′Ga(1-z′)As, which is a quaternary compound semiconductor, are alternately stacked is also applicable to the digital alloy structure.

InGaAs in which GaAs or InAs, which is a binary compound semiconductor, and InzGa(1-z)As, which is a ternary compound semiconductor, are alternately stacked is applicable to the digital alloy structure. A stacked structure in which InAs, GaAs or AlAs which is a binary compound semiconductor, and InAlz′Ga(1-z′)As, which is a quaternary compound semiconductor, are alternately stacked is also applicable to the digital alloy structure. Here, the same is applicable when Al, which constitutes the compound semiconductor materials described above, is replaced by P.

The same can be applied to compound semiconductor material systems with Sb added (InAlAsSb), or the like. Furthermore, InAlGaAsP, which is a quintet compound semiconductor, stacked with InAlGaAs or InGaAsP, which is a quaternary compound semiconductor, is also applicable to the digital alloy structure.

As the digital alloy structure applied to the semiconductor light-receiving device 100 according to Embodiment 1, a combination of the compound semiconductor materials as described above can be appropriately selected, and the periodically stacked structure, in which each layer whose thickness is several monolayers are alternately stacked a plurality of times, produces a lower refractive index n than that of the bulk crystal. As mentioned above, a stacked structure with a thickness between two monolayers and six monolayers is considered optimal for the digital alloy structure. This is because the stacked structure with a thickness of seven monolayers or more may cause unnecessary optical absorption, since each layer functions as a quantum well.

Although the problem of crystal strain is a concern in digital alloy structures, since each layer has a thickness of about several monolayers at most, even if the lattice mismatch degree of each layer is plus a few percent or minus a few percent, crystal growth of the stacked structure is possible as long as the accumulated lattice mismatch degree is small.

As digital alloy structures, the thickness of each layer thereof may be a cycle of one monolayer. However, epitaxial crystal growth for digital alloy structures requires opening and closing the shutter of the epitaxial crystal growth apparatus and switching raw material gases every few monolayers, which takes a long time for epitaxial crystal growth, and thus, from a productivity standpoint, the thickness of each layer thereof is preferably at the several atomic layers level, for example, from two monolayers to six monolayers. Furthermore, in the case of one monolayer, there is a problem that the period is too small to cause a small decrease in the refractive index n.

U.S. Pat. Nos. 6,326,650, 6,436,784, 7,045,833, 6,437,362, and the like disclose APDs with noise reduction or improved high-speed response by applying a superlattice structure or a MQW structure with each layer thickness of several nanometers or more in the multiplier layer.

In contrast, in the present disclosure, the phenomenon of the refractive index n being reduced has been experimentally found for the first time with respect to the digital alloy structure, and furthermore, the optical distribution in the optical waveguide has been successfully controlled by applying the digital alloy structure to the layers constituting waveguide type APDs. That is, principle of operation is different between the digital alloy structure of the present disclosure and the superlattice structure or the MQW structure disclosed in the above-mentioned prior art documents.

In the first place, the APDs disclosed in the above-mentioned prior art documents operate on the basis of principle of operation of ionizing electrons and holes by utilizing the discontinuity of the bandgap between the layers of the superlattice structure or the like, therefore, a periodic superlattice structure composed of each layer with a layer thickness of several nanometers or more is required to generate bandgap discontinuity.

In contrast to the above-mentioned prior art documents, applying the digital alloy structure shown in the present disclosure, in which the thickness of each layer is between two monolayers and six monolayers in period, no individual bandgap of each layer occurs any longer, as described in Non-Patent Document 1, and the bandgap thereof becomes pseudo-uniform similar to bulk crystals. That is, the digital alloy structure of the present disclosure does not exhibit the effect of ionization of electrons and holes caused by the intentional bandgap discontinuity in each of the above-mentioned prior art documents. That is, the superlattice structure applied to the APDs in the above-mentioned prior art documents and the digital alloy structure of the present disclosure are different in principle of operation. Note that in the above-mentioned prior art documents, the phenomenon of the refractive index n being reduced has not found, and there is no description of the possibility of controlling the optical distribution in the optical waveguide by combining the digital alloy structure with waveguide type APDs.

Next, the difference between the APD of Non-Patent Document 1 and the semiconductor light-receiving device 100 according to Embodiment 1 will be described. The cross-sectional structure of the APD is shown in FIG. 1(c) of Non-Patent Document 1. The first difference is that the APD has no light absorption layer, and the multiplication layer with a large bandgap absorbs laser light at a wavelength of 543 nm. The APD in Non-Patent Document 1 has the InGaAs layer with a high carrier concentration of 1×10¹⁹ cm⁻³ as a contact layer located in the vertical direction of the digital alloy layer. However, because of the high carrier concentration thereof, the diffusion length of carriers is short and thus the carriers generated by light absorption are instantly recombined and cannot be extracted as photocurrent. Furthermore, since no electric field is applied due to the high carrier concentration thereof, the InGaAs layer does not function as a light absorption layer.

The second difference is that the APD disclosed in Non-Patent Document 1 is not a light guiding structure, that is, it is not a waveguide type APD. The refractive index of the digital alloy layer is low, and the refractive index of the contact layer portion located in the vertical direction of the digital alloy layer is high, so that light incident from the end surface is scattered to the contact layer portion located in the vertical direction.

The third difference is that the APD disclosed in Non-Patent Document 1 is considered to be a surface-incident type APD in which light is incident from the top or bottom direction of the chip, because its structure is designed to facilitate light incidence for the purpose of noise measurement. This is because, compared to surface-incident type APDs, waveguide type APDs have a light incidence position tolerance that is more than one order of magnitude smaller, so it is not possible to accurately measure noise. For the second reason described above, the APD disclosed in Non-Patent Document 1 is not a waveguide type APD. From the above, it is understood that the APD disclosed in FIG. 1(c) of Non-Patent Document 1 is a surface-incident type APD, unlike the semiconductor light-receiving device 100 according to Embodiment 1 which is a waveguide type APD.

Here, it should be noted that it has been revealed for the first time in the present disclosure that a problem occurs when the digital alloy structure is applied to the multiplication layer of surface-incident type APDs in which light is incident from the upper or lower surface of the chip. As shown in FIG. 3, since the refractive index n is decreased in the multiplication layer composed of the digital alloy structure, the difference in refractive index between the multiplication layer and the light absorption layer or the electric field control layer is increased. When light is incident from the upper or lower surface of the chip, multiple reflection, interference, or resonance due to the difference in refractive index in the multiplication layer portion occurs, thus causing a change in light-receiving sensitivity depending on the wavelength and the phase of the incident light.

For example, consider the case of a light wavelength of 1300 nm, which is commonly used in optical communications. Interference or resonance occurs in a semiconductor material of an optical thickness T at a quarter wavelength. Let the refractive index be n, then, T is as follows.

$$T = 1300 / 4 / n ( nm ) \qquad ( 1 )$$

The refractive index n of DA-InAlAs for the light wavelength of 1300 nm is about 3.2 from FIG. 3. Substituting the above refractive index n into Expression (1), T=101.6 nm. The multiplication layer of APDs used at a high speed of 10 Gbit/sec or 25 Gbit/sec or more generally has a thickness of about 100 nm, and thus the value of T becomes close to 101.6 nm at which resonance occurs, resulting in a maximum light wavelength dependence of the light-receiving sensitivity.

In contrast, the semiconductor light-receiving device 100 according to Embodiment 1 is configured such that light is incident on the multiplication layer composed of the digital alloy structure from the end surface direction, and thus has an advantage that the incident light wavelength dependence of the light-receiving sensitivity due to interference, which is a problem when the digital alloy structure is applied to the multiplication layer of surface-incident type APDs, does not occur.

That is, the inventors have found for the first time that the refractive index decreases in the digital alloy structure, and have theoretically pointed out that the light wavelength dependence of light-receiving sensitivity increases in the surface-incident type APD of Non-Patent Document 1 composed of the digital alloy structure as the multiplication layer. Furthermore, the inventors have solved the problem of the wavelength dependence of the light-receiving sensitivity by using an edge-incident waveguide type APD with the multiplication layer composed of the digital alloy structure, and also have found that high light-receiving sensitivity can also be achieved for the first time, completing the semiconductor light-receiving device of the present disclosure.

In the above description, the specific semiconductor materials, layer thicknesses, and the like constituting the digital alloy structure have been described in detail for the n-type DA-InAlAs buffer layer 2, the i-type DA-InAlAs multiplication layer 3, and the p-type DA-InAlAs electric field control layer 4 composed of the digital alloy structure among the layers constituting the semiconductor light-receiving device 100 according to Embodiment 1. Meanwhile, the semiconductor material is not limited to the exemplified semiconductor materials. That is, the multiplication layer, the electric field control layer, and the n-type buffer layer may have the following configurations.

The i-type multiplication layer is composed of the digital alloy structure in which first multiplication constituent layers having a thickness M times (2≤M≤6) the thickness of the monolayer, and second multiplication constituent layers having a thickness N times (2≤N≤6) the thickness of the monolayer and having a bandgap energy smaller than that of the first multiplication constituent layer, are alternately stacked a plurality of times.

The p-type electric field control layer is composed of the digital alloy structure in which first electric field control constituent layers having a thickness of P times (2≤P≤6) the thickness of the monolayer, and second electric field control constituent layers having a thickness of Q times (2≤Q≤6) the thickness of the monolayer and having a bandgap energy smaller than that of the first electric field control constituent layer, are alternately stacked a plurality of times.

The n-type buffer layer is composed of the digital alloy structure in which first buffer constituent layers having a thickness R times (2≤R≤6) the thickness of the monolayer and second buffer constituent layers having a thickness S times (2≤S≤6) the thickness of the monolayer and having a bandgap energy smaller than that of the first buffer constituent layer, are alternately stacked a plurality of times.

### <Method for Manufacturing Semiconductor Light-Receiving Device According to Embodiment 1>

A method for manufacturing a waveguide type APD, which is an example of the semiconductor light-receiving device 100 according to Embodiment 1, will be described below.

The n-type DA-InAlAs buffer layer 2 having a total thickness of 0.1 to 1.0 μm in which the n-type AlAs layers having a thickness of two monolayers and the n-type InAs layers having a thickness of two monolayers are alternately stacked a plurality of times, the i-type DA-InAlAs multiplication layer 3 having a total thickness of 0.05 to 0.4 μm in which the i-type AlAs layers having a thickness of two monolayers and the i-type InAs layers having a thickness of two monolayers are alternately stacked a plurality of times, the p-type DA-InAlAs electric field relaxation layer 4 having a total thickness of 10 to 100 nm in which the p-type AlAs layers having a thickness of two monolayers and the p-type InAs layers having a thickness of two monolayers are alternately stacked a plurality of times, the i-type InGaAs light absorption layer 5 having a thickness of 0.1 to 1.0 μm, and the p-type InP cladding layer 6 having a thickness of 1 to 3 μm are sequentially crystal-grown above the n-type InP substrate 1 by an epitaxial growth method such as metal-organic vapor phase epitaxy (MOVPE) or molecular beam epitaxy (MBE).

After the crystal growth, metal materials such as Ti/Au are deposited on the surface of the p-type InP cladding layer 6 by vapor deposition or the like, and then, the metal materials are patterned to form the p-type electrode 32.

After the processing of the front surface side of the wafer is completed, the back surface side of the n-type InP substrate 1 is ground, and a film of metal materials such as AuGeNi is deposited thereon by vapor deposition or the like to form the n-type electrode 31. The wafer is separated into individual chips by cleavage or the like, whereby the waveguide type APD is completed.

The above is the method for manufacturing the waveguide type APD which is an example of the semiconductor light-receiving device 100 according to Embodiment 1.

### <Operation of Semiconductor Light-Receiving Device According to Embodiment 1>

FIG. 3 shows the results of actual measurement of the wavelength dependence of the refractive index n of each of InP, InAlAs (bulk crystal), and DA-InAlAs. The refractive index n monotonously decreases as the wavelength increases in a wavelength band longer than the absorption edge wavelength of the semiconductor. The absorption edge wavelengths of InAlAs (bulk crystal) and InP are 860 nm and 920 nm, respectively, and thus, in the wavelength band from 1000 nm to 1600 nm, each refractive index n of the semiconductors decreases as the wavelength becomes longer.

At the wavelength of 1300 nm, which is often used in short-distance optical communications, the refractive index n of InP is 3.204, the refractive index n of InAlAs (bulk crystal) is 3.254, and the refractive index n of DA-InAlAs is 3.212. At the wavelength of 1550 nm, which is often used in long-distance optical communications, the refractive index n of InP is 3.166, the refractive index n of InAlAs (bulk crystal) is 3.219, and the refractive index n of DA-InAlAs is 3.169. That is, at both the wavelengths of 1300 nm and 1550 nm, the refractive index n of DA-InAlAs is lower than the refractive index n of InAlAs (bulk crystal) and almost matches the refractive index n of InP.

As described above, the inventors have found for the first time that the refractive index n of the digital alloy structure is smaller than the refractive index n of the bulk crystal (random alloy structure). The refractive index n is considered to be lower in the digital alloy structure because the atoms therein are more regularly arranged than in the bulk crystal (random alloy structure).

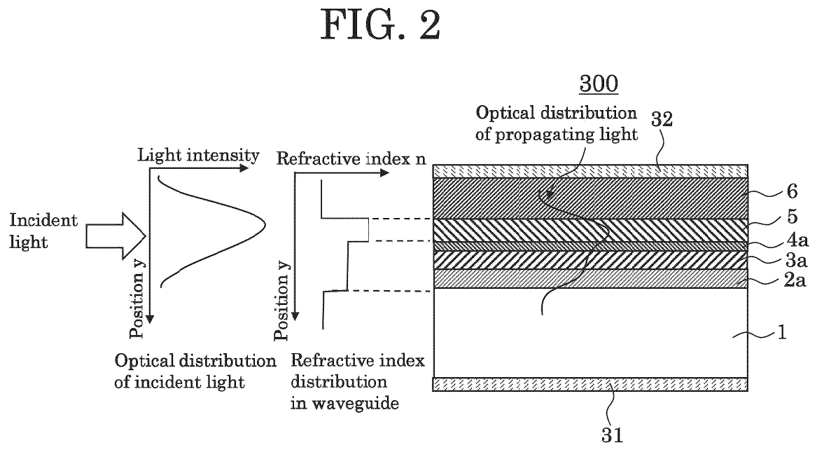

FIG. 2 shows a cross-sectional structure of a waveguide type APD as a comparative example, which is an example of a conventional semiconductor light-receiving device 300, that is, the semiconductor light-receiving device made of ordinary bulk crystals which are not digital alloy structures. The semiconductor light-receiving device 300 includes an n-type InAlAs buffer layer 2a, an i-type InAlAs multiplication layer 3a, a p-type InAlAs electric field control layer 4a, an i-type InGaAs light absorption layer 5, and a p-type InP cladding layer 6, which are sequentially formed above the n-type InP substrate 1, an n-type electrode 31 formed on the back surface of the n-type InP substrate 1, and a p-type electrode 32 formed on the p-type InP cladding layer 6.

As can be seen from the optical distribution of the propagating light shown in FIG. 2, the incident light spreads in the direction of the i-type InGaAs light-absorbing layer 5, as well as in the directions of the i-type InAlAs multiplication layer 3a and the n-type InAlAs buffer layer 2a, reflecting the refractive-index distribution of the waveguide. Consequently, the optical distribution of the propagating light is attracted to the i-type InAlAs multiplication layer 3a side and thus the light confinement ratio of the i-type InGaAs light absorption layer 5 is reduced. That is, the light confinement coefficient of the i-type InGaAs light absorption layer 5 becomes small due to the influence of the spreading the optical distribution of the propagating light. Thus, there is a problem that it is difficult to further improve the light-receiving sensitivity.

In contrast, in the waveguide type APD as an example of the semiconductor light-receiving device 100 according to Embodiment 1, the n-type DA-InAlAs buffer layer 2, the i-type DA-InAlAs multiplication layer 3, and the p-type DA-InAlAs electric field control layer 4 have almost the same value of the refractive index n as that of the InP constituting the p-type InP cladding layer 6, so that only the i-type InGaAs light absorption layer 5 made of InGaAs has a higher refractive index n. Thus, as shown in FIG. 1, the optical distribution of the propagating light is symmetrical in the vertical direction with the i-type InGaAs light absorption layer 5 at the center.

As described above, in the comparative example shown in FIG. 2, the optical distribution of the propagating light is drawn toward the i-type InAlAs multiplication layer 3a side, and thus the light confinement ratio of the i-type InGaAs light absorption layer 5 is reduced. In the semiconductor light-receiving device 100 according to Embodiment 1 shown in FIG. 1, the optical distribution is symmetrical in the vertical direction, and thus the light confinement ratio of the i-type InGaAs light absorption layer 5 increases, thus providing an effect of achieving high light-receiving sensitivity.

### <Effects of Embodiment 1>

As described above, according to the semiconductor light-receiving device of Embodiment 1, at least the multiplication layer and the electric field control layer are composed of the digital alloy structure, thus providing an effect of achieving high light-receiving sensitivity. Furthermore, such high light-receiving sensitivity improves the SN ratio, and thus the light-receiving sensitivity is also improved.

In addition, according to the semiconductor light-receiving device of Embodiment 1, since the light confinement rate of the light absorption layer is high, the waveguide length can be shortened and thus the pn junction capacitance can be reduced, thus providing an effect of achieving a high-speed response. Furthermore, since the light confinement rate of the light absorption layer is high, the thickness of the light absorption layer can be reduced, thus providing an effect of shortening the transit time of electrons and holes and enabling even faster response.

### Embodiment 2

### <Structure of Semiconductor Light-Receiving Device According to Embodiment 2>

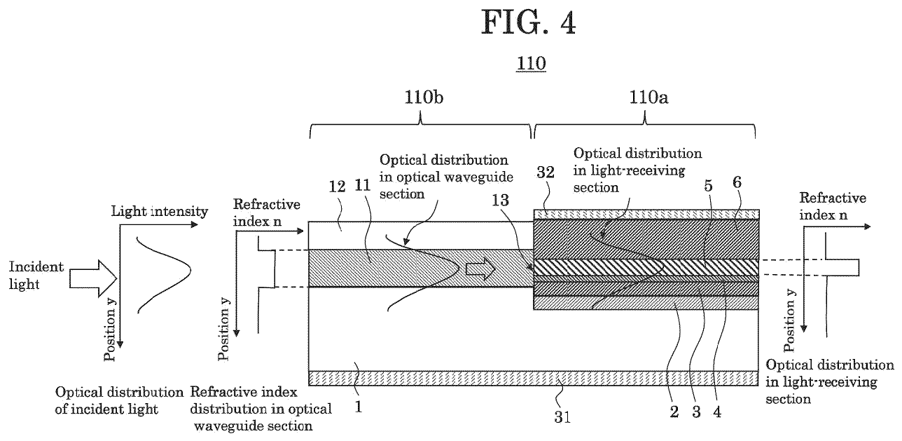

FIG. 4 is a cross-sectional view showing the structure of a semiconductor light-receiving device 110 according to Embodiment 2. A waveguide type APD including an optical waveguide section is given as an example of the semiconductor light-receiving device 110 according to Embodiment 2.

The semiconductor light-receiving device 110 according to Embodiment 2 includes a light-receiving section 110a and an optical waveguide section 110b in contact with the light-receiving section 110a through a connecting section 13, which are formed above a common n-type InP substrate 1.

The light-receiving section 110a has the same structure as the layers constituting the semiconductor light-receiving device 100 according to Embodiment 1. The configuration of each layer has been described in Embodiment 1, and thus the description thereof is omitted here.

The optical waveguide section 110b is composed of an InP cladding layer (not shown because it is made of the same InP as the n-type InP substrate 1) formed above the n-type InP substrate 1, an optical waveguide layer 11 made of InGaAsP or InAlGaAs which is a quaternary compound semiconductor having a bandgap wavelength shorter than that of the light being guided, and an upper InP cladding layer 12. For example, when guiding light having a wavelength of 1300 nm, the bandgap wavelength of the InGaAsP optical waveguide layer 11 is preferably in the range from 1000 nm to 1200 nm.

InP constituting the upper InP cladding layer 12 may be either n-type, p-type, or i-type. The i-type InGaAs light absorption layer 5 of the light-receiving section 110a and the optical waveguide layer 11 of the optical waveguide section 110b are connected such that their heights as viewed from the bottom of the device are almost the same.

When the composition wavelength of the InGaAsP is 1150 nm and InGaAsP is lattice-matched with InP, and the composition ratio of InGaAsP is expressed as In(1-x)Ga(x)As(y)P(1-y), where x=0.18 and y=0.41. The refractive index n of InGaAsP is given by 3.4+0.256y−0.095y², and is thus about 3.5. In contrast, the refractive index n of InGaAs is about 3.6, so the refractive indices n of both InGaAsP and InGaAs are large compared to the refractive index n of the InP cladding layer, which is 3.2. Consequently, as shown in the optical distribution in FIG. 4, light is confined mainly to the optical waveguide layer 11 in the optical waveguide section 110b, whereas light is confined mainly to the i-type InGaAs light absorption layer 5 in the light-receiving section 110a.

Since the refractive index difference Δn with respect to InP is 0.3 for InGaAsP constituting the optical waveguide layer 11, and 0.4 for InGaAs constituting the i-type InGaAs light absorption layer 5, the optimum thickness of the InGaAsP optical waveguide layer 11 is 0.4/0.3=4/3 times the thickness of InGaAs constituting the i-type InGaAs light absorption layer 5. The thickness of InGaAs constituting the i-type InGaAs light absorption layer 5 is in the range of about 0.15 to 0.9 μm. Thus, when the thickness of the InGaAsP optical waveguide layer 11 is set to 0.2 to 1.2 μm, the optical distribution in the InGaAsP optical waveguide layer 11 and the optical distribution in the i-type InGaAs light absorption layer 5 almost coincide with each other. That is, when the thickness dp of the InGaAsP optical waveguide layer 11 and the thickness da of the i-type InGaAs light absorption layer 5 are set to satisfy the following Expression (2), the optical distribution and the equivalent refractive index can be almost identical between the light-receiving section 110a and the optical waveguide section 110b.

$$Δ np : Δ na = da : dp \qquad ( 2 )$$

In the Expression (2), Ana is the refractive index difference between the i-type InGaAs light absorption layer 5 and the p-type InP cladding layer 6, Δnp is the refractive index difference between the InGaAsP optical waveguide layer 11 and the upper InP cladding layer 12, da is the thickness of the i-type InGaAs light absorption layer 5, and dp is the thickness of the InGaAsP optical waveguide layer 11.

### <Operation of Semiconductor Light-Receiving Device According to Embodiment 2>

The left end of FIG. 4 shows the refractive-index distribution of the optical waveguide section 110b, and the right end of FIG. 4 shows the refractive-index distribution of the light-receiving section 110a. As shown in the optical distribution of the incident light in FIG. 4, the light incident on the semiconductor light-receiving device 110 from the lens or the fiber is symmetrical in the vertical direction. Consequently, the optical distribution of the propagating light in the optical waveguide 110b should also be symmetrical in the vertical direction to achieve a higher light coupling efficiency. Meanwhile, the optical distribution of the propagating light of the semiconductor light-receiving device 120, which is a comparative example, is also asymmetric in the vertical direction, as shown in FIG. 2, reflecting the asymmetric refractive-index distribution in the vertical direction. Consequently, if the light-receiving section 110a is configured as the semiconductor light-receiving device 120, which is a comparative example, coupling loss occurs at the connecting section 13 where the optical waveguide section 110b and the light-receiving section 110a contact each other.

In contrast, in the case of the semiconductor light-receiving device 110 according to Embodiment 2, as shown in the optical distribution in the light-receiving section 110a in FIG. 4, the optical distribution is symmetrical in the vertical direction, and thus, the coupling loss in the connecting section 13 can be reduced. Furthermore, if the thickness and the refractive index n of the InGaAsP optical waveguide layer 11 are set so as to satisfy the above-mentioned Expression (2), the optical distribution in the optical waveguide section 110b and the optical distribution in the light-receiving section 110a can be made to almost equal to each other, further reducing the coupling loss in the connecting section 13.

Furthermore, since the equivalent refractive indices of the optical waveguide section 110b and the light-receiving section 110a can be made almost equal to each other by a simple expression such as Expression (2), design of the device is facilitated and design accuracy is also improved. When the equivalent refractive indices of the optical waveguide section 110b and the light-receiving section 110a can be made to equal to each other, the reflected return light from the connecting section 13 can be reduced, and thus, light-receiving sensitivity fluctuation and noise due to interference of light, which is peculiar to integrated devices, can be reduced. If the reflected return light can be reduced, the light-receiving sensitivity of the APD can be improved, and the variation in the light-receiving sensitivity between devices can be also reduced.

### <Effects of Embodiment 2>

As described above, according to the semiconductor light-receiving device of Embodiment 2, in the device structure connecting the optical waveguide section and the light-receiving section, applying the digital alloy structure to the buffer layer, the multiplication layer, and the electric field control layer of the light-receiving section enables the optical distribution in the optical waveguide section and the optical distribution in the light-receiving section to be made almost equal to each other. Therefore, the coupling loss at the connecting section due to the mismatch of optical distribution can be reduced, thus providing an effect that the coupling efficiency between the optical waveguide section and the light-receiving section is improved, which also increases the light-receiving sensitivity of the APD.

Furthermore, the equivalent refractive index at the connecting section can be easily made almost equal to that of the optical waveguide section and the light-receiving section, and thus the reflection at the connecting section is reduced, thus providing an effect of reducing fluctuation in light-receiving sensitivity and noise due to interference of light peculiar to integrated devices.

### Embodiment 3

### <Structure of Semiconductor Light-Receiving Device According to Embodiment 3>

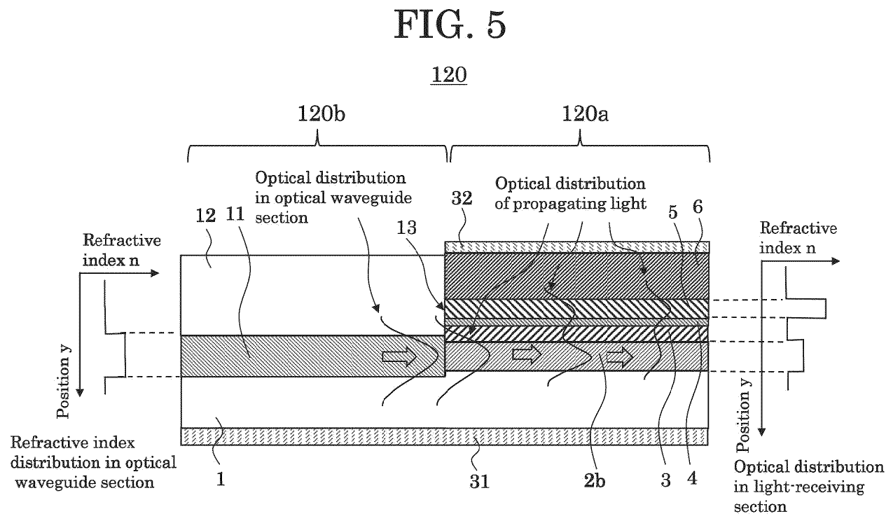

FIG. 5 is a cross-sectional view showing the structure of a semiconductor light-receiving device 120 according to Embodiment 3. A waveguide type APD including an optical waveguide section is given as an example of the semiconductor light-receiving device 120 according to Embodiment 3.

The semiconductor light-receiving device 120 according to Embodiment 3 includes a light-receiving section 120a and an optical waveguide section 120b in contact with the light-receiving section 120a through a connecting section 13, which are formed above a common n-type InP substrate 1.

The light-receiving section 120a includes: an n-type InAlAs buffer layer 2b having a carrier concentration of 1×10¹⁸ to 5×10¹⁸ cm⁻³ and a thickness of 0.1 to 1.0 μm and serving as an optical waveguide layer; an i-type DA-InAlAs multiplication layer 3 having a carrier concentration of 5×10¹⁷ cm⁻³ or less and a total thickness of 0.05 to 0.4 μm and composed of a digital alloy structure in which i-type AlAs layers (for example, a thickness of two monolayers, about 0.5 nm) and i-type InAs layers (for example, a thickness of two monolayers, about 0.5 nm) are alternately stacked a plurality of times; a p-type DA-InAlAs electric field control layer 4 having a carrier concentration of 1×10¹⁶ to 1×10¹⁸ cm⁻³ and a total thickness of 10 to 100 nm and composed of a digital alloy structure in which p-type AlAs layers (for example, a thickness of two monolayers, about 0.5 nm) and p-type InAs layers (for example, a thickness of two monolayers, about 0.5 nm) are alternately stacked a plurality of times; an i-type InGaAs light absorption layer 5 having a thickness of 0.1 to 1.0 μm; a p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

In the above-described configuration, the n-type InAlAs buffer layer 2b may be made of bulk-crystal InAlGaAs or bulk-crystal InGaAsP. In the above-described configuration, the n-type InAlAs buffer layer 2b also serves as an optical waveguide layer, and is provided below the i-type DA-InAlAs multiplication layer 3, that is, on the n-type InP substrate 1 side. The n-type InAlAs buffer layer 2b has a refractive index n higher than that of the n-type InP cladding layer (which is also served by the n-type InP substrate 1). In the above-described configuration, an additional optical waveguide layer may be provided above the n-type InAlAs buffer layer 2b. For example, the n-type InAlAs buffer layer 2b, the InAlGaAs optical waveguide layer, and the i-type DA-InAlAs multiplication layer 3 may be formed in this order above the InP cladding layer.

Since multiplication does not occur in electric field control layers, the electric field control layer is not necessarily composed of DA-InAlAs. Thus, p-type bulk-crystal InP having a low refractive index n may be applied as the electric field control layer.

Between the p-type DA-InAlAs electric field control layer 4 and the i-type InGaAs light absorption layer 5, a transition layer having a thickness of about 0.1 μm or less, which has an intermediate bandgap energy value such as InAlGaAs and InGaAsP, may be provided to prevent the accumulation of electrons and holes. For the same purpose, a transition layer having a thickness of about 0.1 μm or less and made of InAlGaAs or InGaAsP, or the like, which has an intermediate bandgap energy value between that of the i-type InGaAs light absorption layer 5 and that of the p-type InP cladding layer 6, may be provided therebetween.

The optical waveguide section 120b is composed of an InP cladding layer (not shown because it is made of the same InP as the n-type InP substrate 1) formed above the n-type InP substrate 1, an optical waveguide layer 11 made of InGaAsP or InAlGaAs which is a quaternary compound semiconductor having a bandgap wavelength shorter than that of the light being guided, and an upper InP cladding layer 12. For example, when guiding light having a wavelength of 1300 nm, the bandgap wavelength of the InGaAsP optical waveguide layer 11 is preferably in the range from 1000 nm to 1200 nm.

InP constituting the upper InP cladding layer 12 may be either n-type, p-type, or i-type. The n-type InAlAs light buffer layer 2b of the light-receiving section 120a and the optical waveguide layer 11 of the optical waveguide section 120b are connected such that their heights as viewed from the bottom of the device are almost the same. That is, the structure is such that the propagating light guided to the optical waveguide layer 11 of the optical waveguide section 120b is incident on the vicinity of the n-type InAlAs buffer layer 2b positioned below the i-type DA-InAlAs multiplication layer 3.

The semiconductor light-receiving device 120 according to Embodiment 3 has a structure in which AlAs layers (a thickness of two monolayers, about 0.5 nm) and InAs layers (a thickness of two monolayers, about 0.5 nm) are alternately stacked a plurality of times. The thicknesses of the AlAs layer and the InAs layer is preferably within the range from one monolayer to ten monolayers, respectively. Unfortunately, when the thickness of each of the AlAs layer and the InAs layer is one monolayer, the degree of decrease in refractive index n is small. In contrast, when the thickness of each of the AlAs layer and the InAs layer exceeds six monolayers, band discontinuity occurs between each layer. Therefore, a stacked structure consisting of each layer with the thickness between two monolayers and six monolayers is preferable for DA-InAlAs.

A digital alloy structure other than DA-InAlAs, that is, DA-InAlGaAs in which InAlzGa(1-z)As (a thickness is two monolayers or more and six monolayers or less, Al composition ratio z) and InAlz′Ga(1-z′)As (a thickness is two monolayers or more and six monolayers or less, Al composition ratio z′) are alternately crystal-grown a plurality of times can be similarly applied to each layer such as the multiplication layer. Furthermore, a compound semiconductor material system with Sb added, for example, a digital alloy structure composed of a quaternary compound semiconductor material such as InAlAsSb, can also be applied to each layer such as the multiplication layer in the same manner.

The refractive index n of the n-type InAlAs buffer layer 2b, which is made of bulk crystal, is about 3.3. Meanwhile, when the composition wavelength of the InGaAsP that constitutes the InGaAsP optical waveguide layer 11 is 1080 nm and InGaAsP is lattice-matched with InP, and the composition ratio of InGaAsP is expressed as In(1-x)Ga(x)As(y)P(1-y), where x=0.13 and y=0.30. The refractive index n of InGaAsP is given by 3.4+0.256y−0.095y², and is thus about 3.5. The refractive indices n of both the InGaAsP optical waveguide layer 11 and the n-type InAlAs buffer layer 2b are large compared to the refractive index n of the InP cladding layer, which is 3.2. Consequently, in the vicinity of the connecting section 13 where the light-receiving section 120a and the optical waveguide section 120b are in contact with each other, light is confined to the optical waveguide layer 11 and the buffer layer 2b, respectively, as in the optical distribution shown in FIG. 5.

In order to suppress the reflection of the propagating light in the connecting section 13, it is necessary to match the equivalent refractive indices of the light-receiving section 120a and the optical waveguide section 120b as much as possible. Since the refractive index difference Δn with respect to InP is 0.3 for InGaAsP constituting the optical waveguide layer 11, and 0.1 for the InAlAs constituting the n-type InAlAs buffer layer 2b, the optimum thickness of the InGaAsP optical waveguide layer 11 is 0.1/0.3=1/3 times the thickness of InAlAs constituting the n-type InAlAs buffer layer 2b.

The thickness of the n-type InAlAs buffer layer 2b is in the range of about 0.3 to 0.9 μm. Thus, when the thickness of the InGaAsP optical waveguide layer 11 is set to 0.1 to 0.3 μm, the optical distribution in the InGaAsP optical waveguide layer 11 and the optical distribution in the n-type InAlAs buffer layer 2b almost coincide with each other. That is, when the thickness of the InGaAsP optical waveguide layer 11 and the thickness of n-type InAlAs buffer layer 2b are set to satisfy the following Expression (3), the optical distribution and the equivalent refractive index can be almost identical between the light-receiving section 120a and the optical waveguide section 120b.

$$Δ np : Δ nb = db : dp \qquad ( 3 )$$

In Expression (3), Δnp is the difference in the refractive index between the InGaAsP optical waveguide layer 11 and the upper InP cladding layer 12, Δnb is the difference in the refractive index between the n-type InAlAs buffer layer 2b and the InP cladding layer, db is the thickness of the n-type InAlAs buffer layer 2b, and dp is the thickness of the InGaAsP optical waveguide layer 11.

### <Operation of Semiconductor Light-Receiving Device According to Embodiment 3>

The operation of the semiconductor light-receiving device 120 according to Embodiment 3 will be described with reference to FIG. 5. The propagating light propagated through the optical waveguide section 120b passes through the connecting section 13 and enters the n-type InAlAs buffer layer 2b of the light-receiving section 120a. The optical distribution in the n-type InAlAs buffer layer 2b is formed to almost match the optical distribution in the InGaAsP optical waveguide layer 11 of the optical waveguide section 120b, that is, so as to satisfy Expression (3). As a result, the coupling loss at the connecting section 13 is suppressed. Furthermore, since the equivalent refractive indices of the light-receiving section 120a and the optical waveguide section 120b are almost equal to each other, reflected return light, which is a problem in integrated devices, is reduced. If the refractive index n of the multiplication layer is high, radiation loss and reflected return light are generated in the connecting section 13. However, the semiconductor light-receiving device 120 according to Embodiment 3 has the digital alloy structure with a low refractive index n, thus providing an effect of reducing radiation loss and reflected return light at the connecting section 13.

The light incident on the n-type InAlAs buffer layer 2b propagates while gradually shifting toward the i-type InGaAs light absorption layer 5 having a higher refractive index n due to evanescent coupling. The evanescent-coupling type APDs have an advantage that the light absorption in the connecting section 13 does not become too large, and the light is gradually absorbed in the light absorption layer while the light travels, so that the photocurrent density is averaged in the traveling direction of the waveguide. When the photocurrent density is uniform in the waveguide direction, the space charge effect is suppressed even when a large amount of light is incident, and thus the multiplication factor is not reduced. That is, the effect of improving the receiver dynamic range of the APD is achieved.

Meanwhile, conventional evanescent-coupled type APDs use bulk-crystal InAlAs, with a relatively large refractive index n, for the multiplication layer, which causes a large amount of light leakage into the light absorption layer. As a result, the light absorption in the vicinity of the connecting section increases, which means that the photocurrent density increases, thus limiting the receiver dynamic range. In contrast, configuration such as the semiconductor light-receiving device 120 according to Embodiment 3 enables a significant improvement in the receiver dynamic range.

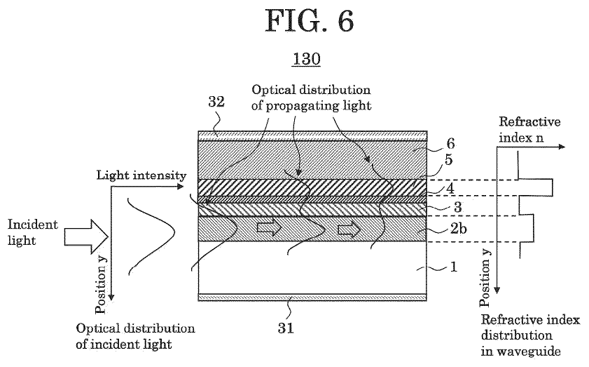

The effect of improving the receiver dynamic range can be similarly obtained even in a device structure in which the optical waveguide section is not connected as shown in FIG. 6, for example. The waveguide type APD, which is an example of the semiconductor light-receiving device 130 shown in FIG. 6, has the same configuration as the semiconductor light-receiving device 120 shown in FIG. 5 except that the optical waveguide section is not provided. That is, the semiconductor light-receiving device 130 has the same configuration as the light-receiving section 120a of the semiconductor light-receiving device 120.

In the case of the semiconductor light-receiving device 130 shown in FIG. 6, light coming from the lens or the fiber enters the n-type InAlAs buffer layer 2b or the optical waveguide layer (not shown) located below the i-type DA-InAlAs multiplication layer 3. As in the device structure shown in FIG. 5, the semiconductor light-receiving device 130 has the i-type DA-InAlAs multiplication layer 3 with a low refractive index n, so that light incident from the end surface propagates into the i-type InGaAs light absorption layer 5 while being gradually transferred thereto, which suppresses the decrease in multiplication factor when light with high light intensity is incident, thus providing an effect of improving the receiver dynamic range.

### <Effects of Embodiment 3>

As described above, the semiconductor light-receiving device according to Embodiment 3, the semiconductor light-receiving device has the digital alloy structure with a low refractive index for the multiplication layer and is an evanescent-waveguide type APD in which light enters the buffer layer, which also serves as the optical waveguide layer, below the multiplication layer, thereby suppressing light radiation loss and reflected return light at the connecting section between the optical waveguide section and the light-receiving section. Furthermore, the semiconductor light-receiving device according to Embodiment 3 is designed to apply the digital alloy structure with a low refractive index to the multiplication layer so that light is gradually transferred to the light absorption layer, thereby suppressing light absorption in the vicinity of the connecting section and suppressing the decrease in the multiplication factor when a large amount of light is incident, thus providing an effect of improving in receiver dynamic range.

### Embodiment 4

### <Structure of Semiconductor Light-Receiving Device According to Embodiment 4>

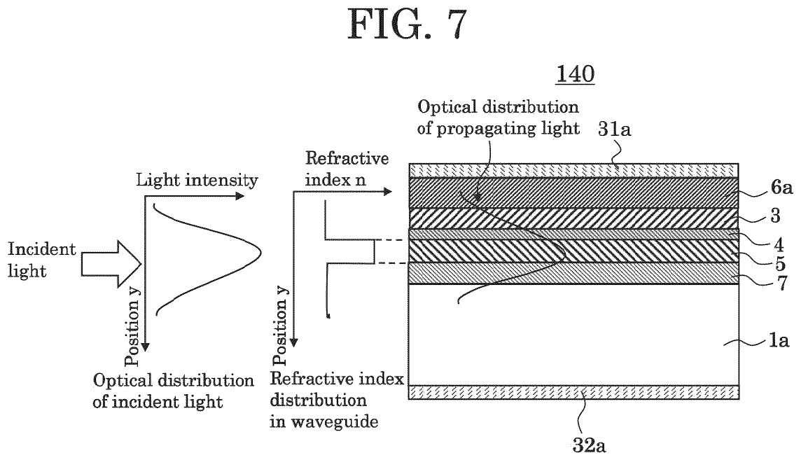

FIG. 7 is a cross-sectional view showing the structure of a semiconductor light-receiving device 140 according to Embodiment 4. A waveguide type APD is given as an example of the semiconductor light-receiving device 140 according to Embodiment 4. The semiconductor light-receiving device of Example 4 has a device structure in which the pn junction is vertically inverted with respect to the semiconductor light-receiving device 100 according to Embodiment 1.

The semiconductor light-receiving device 140 according to Embodiment 4 includes: a p-type InP cladding layer 7 having a carrier concentration of 1×10¹⁷ to 1×10¹⁹ cm⁻³ and a thickness of 0.1 to 10 μm and serving as an optical waveguide layer; an i-type InGaAs light absorption layer 5 having a thickness of 0.1 to 1.0 μm; a p-type DA-InAlAs electric field control layer 4 having a carrier concentration of 1×10¹⁶ to 1×10¹⁸ cm⁻³ and a total thickness of 10 to 100 nm and composed of a digital alloy structure in which p-type AlAs layers (for example, a thickness of two monolayers, about 0.5 nm) and p-type InAs layers (for example, a thickness of two monolayers, about 0.5 nm) are alternately stacked a plurality of times; an i-type DA-InAlAs multiplication layer 3 having a carrier concentration of 5×10¹⁷ cm⁻³ or less and a total thickness of 0.05 to 0.4 μm and composed of a digital alloy structure in which i-type AlAs layers (for example, a thickness of two monolayers, about 0.5 nm) and i-type InAs layers (for example, a thickness of two monolayers, about 0.5 nm) are alternately stacked a plurality of times; an n-type InP cladding layer 6a having a carrier concentration of 5×10¹⁷ to 1×10¹⁹ cm⁻³ and a thickness of 1 to 3 μm; an n-type electrode 31 formed on a back surface of a semi-insulating InP substrate 1a; and a p-type electrode 32 formed above the surface of the n-type InP cladding layer 6a, wherein above layers are sequentially formed above the semi-insulating InP substrate 1a.

Since multiplication does not occur in electric field control layers, the electric field control layer is not necessarily composed of DA-InAlAs. Thus, p-type bulk-crystal InP having a low refractive index n may be applied as the electric field control layer.

The p-type InP cladding layer 7 also serves as a conductive layer. Instead of the p-type InP cladding layer 7, a p-type cladding layer made of p-type InGaAsP or p-type InGaAs, or a p-type cladding layer composed of a stacked structure of any of p-type InP, p-type InGaAsP, p-type InGaAs, and p-type InAlGaAs may be substituted.

The p-type electrode 32a is electrically connected to the p-type InP cladding layer 7. For example, one method for making contact therebetween is to partially remove the layer below the p-type InP cladding layer 7.

### Modification 1 of Embodiment 4

### <Structure of Semiconductor Light-Receiving Device According to Modification 1 of Embodiment 4>

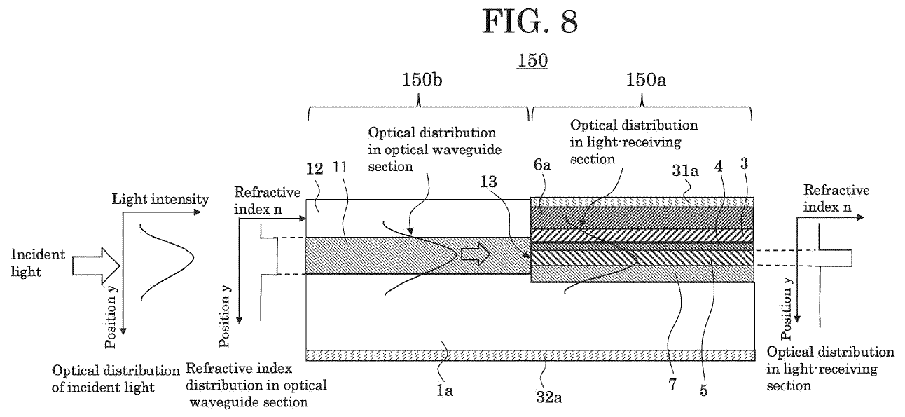

FIG. 8 is a cross-sectional view showing the structure of a semiconductor light-receiving device 150 according to Modification 1 of Embodiment 4. A waveguide type APD including an optical waveguide section is given as an example of the semiconductor light-receiving device 150 according to Modification 1 of Embodiment 4.

The semiconductor light-receiving device 150 according to Modification 1 of Embodiment 4 includes a light-receiving section 150a and an optical waveguide section 150b connected to the light-receiving section 150a through a connecting section 13, which are formed above a common semi-insulating InP substrate 1a.

The light-receiving section 150a has the same structure as the layers constituting the semiconductor light-receiving device 140 according to Embodiment 4. The configuration of each layer has been described in Embodiment 4, and thus the description thereof is omitted here.

The optical waveguide section 150b is composed of an InP cladding layer (not shown because it is made of the same InP as the semi-insulating InP substrate 1a) formed above the semi-insulating InP substrate 1a, an optical waveguide layer 11 made of InGaAsP or InAlGaAs which is a quaternary compound semiconductor having a bandgap wavelength shorter than that of the light being guided, and an upper InP cladding layer 12. For example, when guiding light having a wavelength of 1300 nm, the bandgap wavelength of the InGaAsP optical waveguide layer 11 is preferably in the range from 1000 nm to 1200 nm.

The InP constituting the upper InP cladding layer 12 may be either n-type, p-type, or i-type. The i-type InGaAs light absorption layer 5 of the light-receiving section 150a and the i-type InGaAsP optical waveguide layer 11 of the optical waveguide section 150b are connected such that their heights as viewed from the bottom of the device are almost the same.

### Modification 2 of Embodiment 4

### <Structure of Semiconductor Light-Receiving Device According to Modification 2 of Embodiment 4>

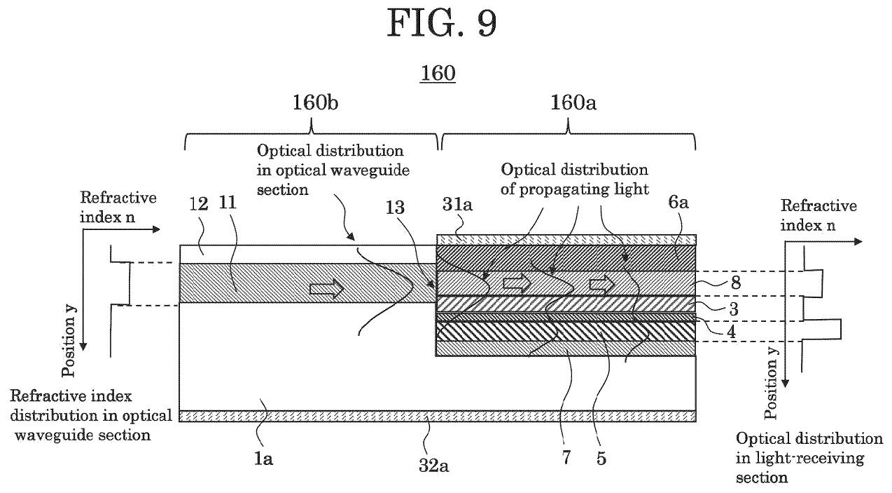

FIG. 9 is a cross-sectional view showing the structure of a semiconductor light-receiving device 160 according to Modification 2 of Embodiment 4. A waveguide type APD including an optical waveguide section is given as an example of the semiconductor light-receiving device 160 according to Modification 2 of Embodiment 4.

The semiconductor light-receiving device 160 according to Modification 2 of Embodiment 4 includes a light-receiving section 160a and an optical waveguide section 160b connected to the light-receiving section 160a through a connecting section 13, which are formed above a common semi-insulating InP substrate 1a. The semiconductor light-receiving device 160 according to Modification 2 of Embodiment 4 has a device structure in which an optical waveguide section and an evanescent-coupling type light-receiving section are connected to each other, similarly to the semiconductor light-receiving device 120 according to Embodiment 3 shown in FIG. 5.

The light-receiving section 160a has almost the same structure as the layers constituting the light-receiving device 140 according to Embodiment 4, except that an n-type InAlAs optical waveguide layer 8 is provided above the i-type DA-InAlAs multiplication layer 3. The n-type InAlAs optical waveguide layer 8 has a thickness of 0.1 to 1 μm and a carrier concentration of 1×10¹⁷ to 1×10¹⁹ cm⁻³. The n-type optical waveguide layer may be made of n-type InGaAsP or n-type InAlGaAs, or may be composed of a stacked structure of n-type InGaAsP or n-type InAlGaAs.

In the semiconductor light-receiving device 160 according to Modification 2 of Embodiment 4, the n-type electrode 31a is formed on the upper surface side, and the p-type electrode 32a is electrically connected to the p-type InP cladding layer 7 below the i-type InGaAs light absorption layer 5, as in the semiconductor light-receiving device 140 according to Embodiment 4. As in the semiconductor light-receiving device 120 according to Embodiment 3, the InGaAsP optical waveguide layer 11 of the optical waveguide section 160b is in contact with the n-type InAlAs optical waveguide layer 8 of the light-receiving section 160a.

### Modification 3 of Embodiment 4

### <Structure of Semiconductor Light-Receiving Device According to Modification 3 of Embodiment 4>

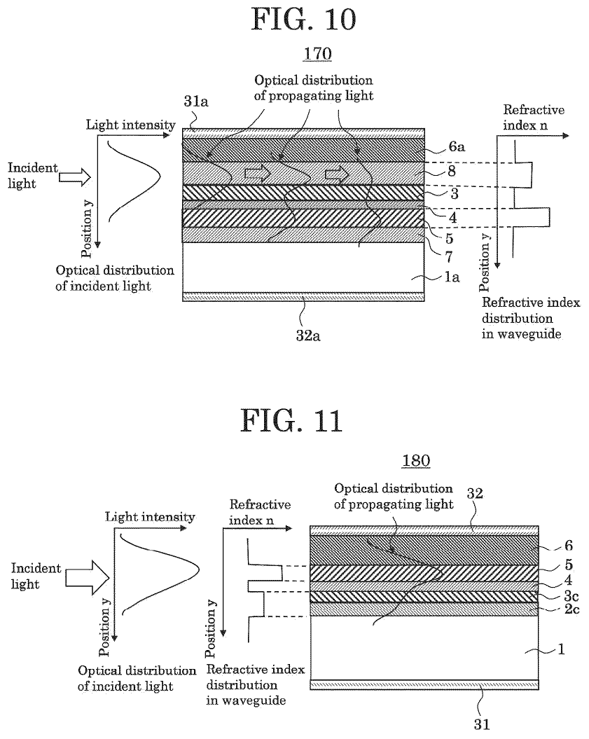

FIG. 10 is a cross-sectional view showing the structure of a semiconductor light-receiving device 170 according to Modification 3 of Embodiment 4. A waveguide type APD including an optical waveguide section is given as an example of the semiconductor light-receiving device 170 according to Modification 3 of Embodiment 4.

The semiconductor light-receiving device 170 according to Modification 3 of Embodiment 4 has a structure in which the optical waveguide section 160b is removed from the semiconductor light-receiving device 160 according to Modification 2 of Embodiment 4, and only the light-receiving section 160a is provided.

The semiconductor light-receiving device 170 according to Modification 3 of Embodiment 4 has a structure in which light is incident on the n-type InAlAs optical waveguide layer 8 from the end surface.

### <Effects of Semiconductor Light-Receiving Devices According to Embodiment 4 and Modifications 1 to 3 of Embodiment 4>

In waveguide type APDs, in order to obtain a high-speed response and a wide receiver dynamic range, a carrier concentration of an electric field control layer is set such that a high electric field is applied to a light absorption layer. Since the light absorption layer has the narrowest bandgap among the semiconductor materials constituting waveguide type APDs (in the case of InGaAs, the bandgap wavelength is 1670 nm), tunneling current and generation-recombination current are generated, resulting in increased dark current. To reduce the generation-recombination current, it is preferable to stack InGaAs, which constitutes the light absorption layer, on a lattice-matched crystal.

In any of Embodiment 1 to Embodiment 3, the device structure has the i-type InGaAs light absorption layer 5 that is crystal-grown above the i-type DA-InAlAs multiplication layer 3 composed of the digital alloy structure. In forming the digital alloy structure, crystals are grown by alternately stacking compressively strained and tensile strained layers such that the entire structure is substantially strain-free. For example, the digital alloy structure made of InAlAs is a semiconductor layer in which AlAs layers (a thickness is two monolayers, about 0.5 nm) and InAs layers (a thickness is two monolayers, about 0.5 nm) are alternately stacked a plurality of times.

The lattice spacing of InAs is 0.618 nm and that of AlAs is 0.566 nm, which is mismatched with that of the substrate, InP, which is 0.588 nm, so that compressive and tensile strains are applied alternately to each layer. When the strain is alternately applied, the entire strain of the i-type DA-InAlAs multiplication layer 3 is canceled out, but some residual strain may remain depending on the variation in the layer thickness during crystal growth. There is a concern that crystal growth of an InGaAs layer with a narrow bandgap, which constitutes the i-type InGaAs light absorption layer 5, on a crystal with residual strain may cause crystal defects and dislocations that are sources of the generation-recombination current. That is, providing the i-type InGaAs light absorption layer 5 above the layer composed of the digital alloy structure may increase the manufacturing variation of dark current.

In contrast, in the semiconductor light-receiving devices 140, 150, 160, and 170 according to Embodiment 4 and Modifications 1 to 3 of Embodiment 4, the digital alloy structures constituting the i-type DA-InAlAs multiplication layer 3 and the p-type DA-InAlAs electric field control layer 4 are crystal-grown after the crystal growth of the i-type InGaAs light absorption layer 5. Consequently, the i-type InGaAs light absorption layer 5 can be crystal-grown on a strain-free InP layer. Therefore, crystal defects and dislocations that are sources of generation-recombination current are reduced in the i-type InGaAs light absorption layer 5, thus providing an effect of reducing manufacturing variations in dark current of a semiconductor light-receiving device.

### <Effects of Embodiment 4 and Modifications 1 to 3 of Embodiment 4>

As described above, in addition to the effect of the semiconductor light-receiving devices according to Embodiments 1 to 3, the semiconductor light-receiving devices according to Embodiment 4 and Modifications 1 to 3 of Embodiment 4 have the effect of reducing the manufacturing variation of dark current, because the light absorption layer in which the dark current is likely to occur can be crystal-grown above the strain-free cladding layer also serving as the optical waveguide layer, instead of the upper side of the digital alloy structure in which the residual strain is likely to occur. Furthermore, since crystal defects and dislocations are suppressed in the light absorption layer, recombination of carriers generated by light absorption can be prevented, thus providing an effect of improving quantum efficiency.

### Embodiment 5

### <Structure of Semiconductor Light-Receiving Device According to Embodiment 5>

FIG. 11 is a cross-sectional view showing the structure of a semiconductor light-receiving device 180 according to Embodiment 5. A waveguide type APD is given as an example of the semiconductor light-receiving device 180 according to Embodiment 5.

The semiconductor light-receiving device 180 according to Embodiment 5 includes: an n-type InAlAs buffer layer 2c having a carrier concentration of 1×10¹⁸ to 5×10¹⁸ cm⁻³ and a thickness of 0.1 to 1.0 μm; an i-type InAlAs multiplication layer 3c having a carrier concentration of 5×10¹⁷ cm⁻³ or less and a thickness of 0.05 to 0.4 μm; a p-type DA-InAlAs electric field control layer 4 having a carrier concentration of 1×10¹⁶ to 1×10¹⁸ cm⁻³ and a total thickness of 10 to 100 nm and composed of a digital alloy structure in which p-type AlAs layers (for example, a thickness of two a monolayers, about 0.5 nm) and p-type InAs layers (for example, a thickness of two monolayers, about 0.5 nm) are alternately stacked a plurality of times; an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

The semiconductor light-receiving device 180 according to Embodiment 5 is characterized in that only the electric field control layer is composed of the digital alloy structure.

### Modification 1 of Embodiment 5

### <Structure of Semiconductor Light-Receiving Device According to Modification 1 of Embodiment 5>

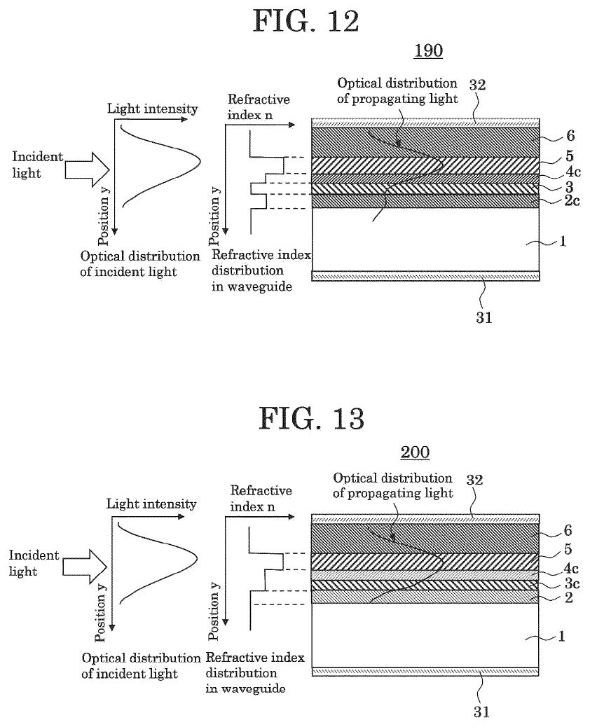

FIG. 12 is a cross-sectional view showing the structure of a semiconductor light-receiving device 190 according to Modification 1 of Embodiment 5. A waveguide type APD is given as an example of the semiconductor light-receiving device 190 according to Modification 1 of Embodiment 5.

The semiconductor light-receiving device 190 according to Modification 1 of Embodiment 5 includes: an n-type InAlAs buffer layer 2c having a carrier concentration of 1×10¹⁸ to 5×10¹⁸ cm⁻³ and a thickness of 0.1 to 1.0 μm; an i-type DA-InAlAs multiplication layer 3 having a carrier concentration of 5×10¹⁷ cm⁻³ or less and a total thickness of 0.05 to 0.4 μm and composed of a digital alloy structure in which i-type AlAs layers (for example, a thickness of two monolayers, about 0.5 nm) and i-type InAs layers (for example, a thickness of two monolayers, about 0.5 nm) are alternately stacked a plurality of times; a p-type InAlAs electric field control layer 4c having a carrier concentration of 1×10¹⁶ to 1×10¹⁸ cm⁻³ and a thickness of 10 to 100 nm; an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

The semiconductor light-receiving device 190 according to Modification 1 of Embodiment 5 is characterized in that only the multiplication layer is composed of the digital alloy structure.

### Modification 2 of Embodiment 5

### <Structure of Semiconductor Light-Receiving Device According to Modification 2 of Embodiment 5>

FIG. 13 is a cross-sectional view showing the structure of a semiconductor light-receiving device 200 according to Modification 2 of Embodiment 5. A waveguide type APD is given as an example of the semiconductor light-receiving device 200 according to Modification 2 of Embodiment 5.

The semiconductor light-receiving device 200 according to Modification 2 of Embodiment 5 includes: an n-type DA-InAlAs buffer layer 2 having a carrier concentration of 1×10¹⁸ to 5×10¹⁸ cm⁻³ and a total thickness of 0.1 to 1.0 μm and composed of a digital alloy structure in which n-type AlAs layers (for example, a thickness of two monolayers, about 0.5 nm) and n-type InAs layers (for example, a thickness of two monolayers, about 0.5 nm) are alternately stacked a plurality of times; an i-type InAlAs multiplication layer 3c having a carrier concentration of 5×10¹⁷ cm⁻³ or less and a thickness of 0.05 to 0.4 μm; a p-type InAlAs electric field control layer 4c having a carrier concentration of 1×10¹⁶ to 1×10¹⁸ cm⁻³ and a thickness of 10 to 100 nm; an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

The semiconductor light-receiving device 200 according to Modification 2 of Embodiment 5 is characterized in that only the multiplication layer is composed of the digital alloy structure.

In the semiconductor light-receiving device 180 according to Embodiment 5, the semiconductor light-receiving device 190 according to Modification 1 of Embodiment 5, and the semiconductor light-receiving device 200 according to Modification 2 of Embodiment 5, a transition layer having a thickness of 0.1 μm or less and made of a compound semiconductor material such as InAlGaAs or InGaAsP may be provided between the p-type DA-InAlAs electric field control layer 4 or the p-type InAlAs electric field control layer 4c and the i-type InGaAs light absorption layer 5. InAlGaAs or InGaAsP constituting the transition layer has a bandgap energy value intermediate between the bandgap energy value of InAlAs constituting the p-type DA-InAlAs electric field control layer 4 or the p-type InAlAs electric field control layer 4c and the bandgap energy value of InGaAs constituting the i-type InGaAs light absorption layer 5. Providing such a transition layer enables to prevent the accumulation of electrons and holes at the heterojunction interface.

For the same purpose as the above-mentioned transition layer, a transition layer having a thickness of 0.1 μm or less and made of a compound semiconductor material such as InAlGaAs or InGaAsP may be provided between the i-type InGaAs light absorption layer 5 and the p-type InP cladding layer 6. InAlGaAs or InGaAsP constituting the transition layer has a bandgap energy value intermediate between the bandgap energy of InGaAs constituting the i-type InGaAs light absorption layer 5 and the bandgap energy of InP constituting the p-type InP cladding layer 6. Providing such a transition layer enables to prevent the accumulation of electrons and holes at the heterojunction interface.

In the semiconductor light-receiving device 100 according to Embodiment 1, all of the n-type DA-InAlAs buffer layer 2, the i-type DA-InAlAs multiplication layer 3, and the p-type DA-InAlAs electric field control layer 4 are composed of DA-InAlAs structure. Meanwhile, the semiconductor light-receiving device 180 according to Embodiment 5, the semiconductor light-receiving device 190 according to Modification 1 of Embodiment 5, and the semiconductor light-receiving device 200 according to Modification 2 of Embodiment 5 apply the DA-InAlAs structure to any one of the buffer layer, the multiplication layer, and the electric field control layer. Furthermore, configurations in which the DA-InAlAs structure is applied to a portion of each of the buffer layer, the multiplication layer, and the electric field control layer are also included in Embodiment 5, Modification 1 of Embodiment 5, and Modification 2 of Embodiment 5.

### <Operation of Semiconductor Light-Receiving Devices According to Embodiment 5, Modification 1 of Embodiment 5, and Modification 2 of Embodiment 5>

When the refractive index is different between the lower layer (substrate side) and the upper layer (upper surface side) with respect to the light absorption layer, the propagation mode of light is asymmetric in the vertical direction as described in Embodiment 1. The degree of asymmetry in the vertical direction depends on the following Expression (4). The propagation mode of light is biased toward the substrate side as the value of Expression (4) increases.

$$Γ a \times Δ na \times T + Γ b \times Δ nb \times Tb + Γ c \times Δ nc \times Tc \qquad ( 4 )$$

In Expression (4), Pa, Pb, and Pc are optical confinement coefficients of the electric field control layer, the multiplication layer, and the buffer layer, respectively. Δna, Δnb, and Δnc are the differences between the refractive index of the electric field control layer, the multiplication layer, and the buffer layer, and the refractive index of InP, respectively. Ta, Tb, and Tc are the thicknesses of the electric field control layer, the multiplication layer, and the buffer layer, respectively.

If the value of the Expression (4) is made as small as possible, the asymmetry of the propagation mode of light in the vertical direction is reduced. Consequently, using the digital alloy structure for any one or part of one of the electric field control layer, the multiplication layer, or the buffer layer enables Δna, Δnb, or Δnc to be reduced.

### <Effects of Embodiment 5, Modification 1 of Embodiment 5, and Modification 2 of Embodiment 5>

As described above, according to the semiconductor light-receiving devices of Embodiment 5, Modification 1 of Embodiment 5, and Modification 2 of Embodiment 5, since any one or part of one of the electric field control layer, the multiplication layer, or the buffer layer is composed of the digital alloy structure, the propagation mode of light in the waveguide type APD is symmetrical in the vertical direction, resulting in high light-receiving sensitivity. Furthermore, the high light-receiving sensitivity improves the SN ratio, thus providing an effect that the light-receiving sensitivity is also improved.

The semiconductor light-receiving devices according to Embodiment 5, Modification 1 of Embodiment 5, and Modification 2 of Embodiment 5 have a smaller effect of reducing the asymmetry of the light propagation mode than the semiconductor light-receiving device according to Embodiment 1 in which all of the electric field control layer, the multiplication layer, and the buffer layer are composed of the digital alloy structure. However, the number of times to switch elements in the MOVPE or the MBE apparatus used for crystal growth of each layer is reduced, thus providing an effect of shortening the crystal growth time and reducing wear and tear of the MOVPE or the MBE apparatus.

### Embodiment 6

### <Structure of Semiconductor Light-Receiving Device According to Embodiment 6>

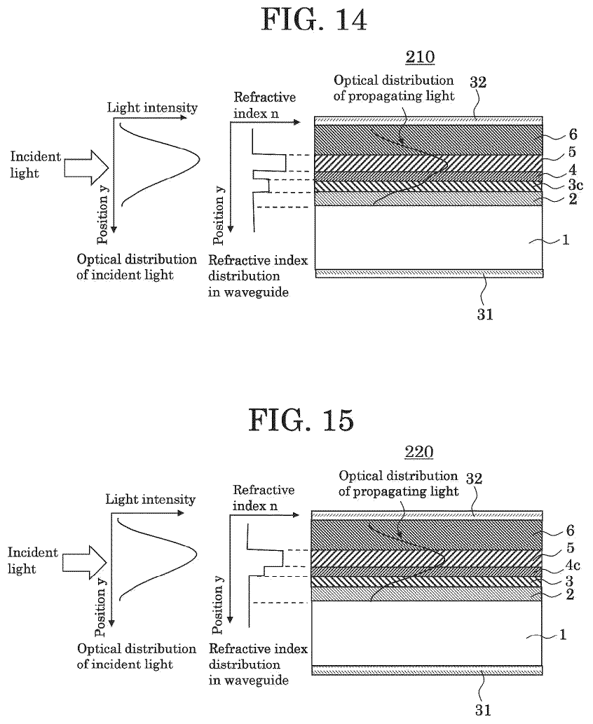

FIG. 14 is a cross-sectional view showing the structure of a semiconductor light-receiving device 210 according to Embodiment 6. A waveguide type APD is given as an example of the semiconductor light-receiving device 210 according to Embodiment 6.

The semiconductor light-receiving device 210 according to Embodiment 6 includes: an n-type DA-InAlAs buffer layer 2 having a carrier concentration of 1×10¹⁸ to 5×10¹⁸ cm⁻³ and a total thickness of 0.1 to 1.0 μm and composed of a digital alloy structure in which n-type AlAs layers (for example, a thickness of two monolayers, about 0.5 nm) and n-type InAs layers (for example, a thickness of two monolayers, about 0.5 nm) are alternately stacked a plurality of times; an i-type InAlAs multiplication layer 3c having a carrier concentration of 5×10¹⁷ cm⁻³ or less and a thickness of 0.05 to 0.4 μm; a p-type DA-InAlAs electric field control layer 4 having a carrier concentration of 1×10¹⁶ to 1×10¹⁸ cm⁻³ and a total thickness of 10 to 100 nm and composed of a digital alloy structure in which p-type AlAs layers (for example, a thickness of two monolayers, about 0.5 nm) and p-type InAs layers (for example, a thickness of two monolayers, about 0.5 nm) are alternately stacked a plurality of times; an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

The semiconductor light-receiving device 210 according to Embodiment 6 is characterized in that only the buffer layer and the electric field control layer are composed of the digital alloy structure.

### Modification 1 of Embodiment 6

### <Structure of Semiconductor Light-Receiving Device According to Modification 1 of Embodiment 6>

FIG. 15 is a cross-sectional view showing the structure of a semiconductor light-receiving device 220 according to Modification 1 of Embodiment 6. A waveguide type APD is given as an example of the semiconductor light-receiving device 220 according to Modification 1 of Embodiment 6.

The semiconductor light-receiving device 220 according to Modification 1 of Embodiment 6 includes: an n-type DA-InAlAs buffer layer 2 having a carrier concentration of 1×10¹⁸ to 5×10¹⁸ cm⁻³ and a total thickness of 0.1 to 1.0 μm and composed of a digital alloy structure in which n-type AlAs layers (for example, a thickness of two monolayers, about 0.5 nm) and n-type InAs layers (for example, a thickness of two monolayers, about 0.5 nm) are alternately stacked a plurality of times; an i-type InAlAs multiplication layer 3 having a carrier concentration of 5×10¹⁷ cm⁻³ or less and a total thickness of 0.05 to 0.4 μm and composed of a digital alloy structure in which i-type AlAs layers (for example, a thickness of two monolayers, about 0.5 nm) and i-type InAs layers (for example, a thickness of two monolayers, about 0.5 nm) are alternately stacked a plurality of times; a p-type InAlAs electric field control layer 4c having a carrier concentration of 1×10¹⁶ to 1×10¹⁸ cm⁻³ and a thickness of 10 to 100 nm; an i-type InGaAs light absorption layer 5 having a thickness of 0.1 to 1.0 μm; an p-type InP cladding layer 6 having a thickness of 1 to 3 μm; an n-type electrode 31 formed on a back surface of an n-type InP substrate 1; and a p-type electrode 32 formed above the surface of the p-type InP cladding layer 6, wherein above layers are sequentially formed above the n-type InP substrate 1.

The semiconductor light-receiving device 220 according to Modification 1 of Embodiment 6 is characterized in that only the buffer layer and the multiplication layer are composed of the digital alloy structure.

In the semiconductor light-receiving device 210 according to Embodiment 6 and the semiconductor light-receiving device 220 according to Modification 1 of Embodiment 6, a transition layer having a thickness of 0.1 μm or less and made of a compound semiconductor material such as InAlGaAs or InGaAsP may be provided between the p-type DA-InAlAs electric field control layer 4 or the p-type InAlAs electric field control layer 4c and the i-type InGaAs light absorption layer 5. InAlGaAs or InGaAsP constituting the transition layer has a bandgap energy value intermediate between the bandgap energy value of InAlAs constituting the p-type DA-InAlAs electric field control layer 4 or the p-type InAlAs electric field control layer 4c and the bandgap energy value of InGaAs constituting the i-type InGaAs light absorption layer 5. Providing such a transition layer enables to prevent the accumulation of electrons and holes at the heterojunction interface.

For the same purpose as the above-mentioned transition layer, a transition layer having a thickness of 0.1 μm or less and made of a compound semiconductor material such as InAlGaAs or InGaAsP may be provided between the i-type InGaAs light absorption layer 5 and the p-type InP cladding layer 6. InAlGaAs or InGaAsP constituting the transition layer has a bandgap energy value intermediate between the bandgap energy of InGaAs constituting the i-type InGaAs light absorption layer 5 and the bandgap energy of InP constituting the p-type InP cladding layer 6. Providing such a transition layer enables to prevent the accumulation of electrons and holes at the heterojunction interface.

In the semiconductor light-receiving device 100 according to Embodiment 1, all of the n-type DA-InAlAs buffer layer 2, the i-type DA-InAlAs multiplication layer 3, and the p-type DA-InAlAs electric field control layer 4 are composed of DA-InAlAs structure. Meanwhile, the semiconductor light-receiving device 210 according to Embodiment 6 applies the DA-InAlAs structure to both the buffer layer and the electric field control layer. The semiconductor light-receiving device 220 according to Modification 1 of Embodiment 6 applies the DA-InAlAs structure to both the buffer layer and the multiplication layer. Furthermore, configurations in which the DA-InAlAs structure is applied to a portion of each of the buffer layer, the multiplication layer, and the electric field control layer are also included in Embodiment 6 and Modification 1 of Embodiment 6.

### <Effects of Embodiment 6 and Modification 1 of Embodiment 6>

As described above, according to the semiconductor light-receiving devices of Embodiment 6 and Modification 1 of Embodiment 6, since any two or part of two of the electric field control layer, the multiplication layer, or the buffer layer are composed of the digital alloy structure, the propagation mode of light in the waveguide type APD is symmetrical in the vertical direction, resulting in high light-receiving sensitivity. Furthermore, the high light-receiving sensitivity improves the SN ratio, thus providing an effect that the light-receiving sensitivity is also improved.

The semiconductor light-receiving devices according to Embodiment 6 and Modification 1 of Embodiment 6 have a smaller effect of reducing the asymmetry of the light propagation mode than the semiconductor light-receiving device according Embodiment 1 in which all of the electric field control layer, the multiplication layer, and the buffer layer are composed of the digital alloy structure. However, the number of times to switch elements in the MOVPE or the MBE apparatus used for crystal growth of each layer is reduced, thus providing an effect of shortening the crystal growth time and reducing wear and tear of the MOVPE or the MBE apparatus.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type InP substrate
2 n-type DA-InAlAs buffer layer
2a, 2b, 2c n-type InAlAs buffer layer
3 i-type DA-InAlAs multiplication layer
3a, 3c i-type InAlAs multiplication layer
4 p-type DA-InAlAs electric field control layer
4a, 4c p-type InAlAs electric field control layer
5 i-type InGaAs light absorption layer
6, 7 p-type InP cladding layer
6a n-type InP cladding layer
8 n-type InAlAs optical waveguide layer
11 optical waveguide layer
12 upper InP cladding layer
31, 31a n-type electrode
31a, 32 p-type electrode
100, 110, 120, 130, 140, 150, 160, 170, 180, 190,
200, 210, 220, 300 semiconductor light-receiving device
110a 120a 150a 160a light-receiving section
110b 120b 150b 160b optical waveguide section

1. A semiconductor light-receiving device comprising:
a InP substrate;
an n-type InAlAs buffer layer formed above the InP substrate;
an InAlAs multiplication layer formed above the n-type InAlAs buffer layer;
a p-type InAlAs electric field control layer formed above the InAlAs multiplication layer; and
an InGaAs light absorption layer formed above the p-type InAlAs electric field control layer; wherein
either two layers of the InAlAs multiplication layer and the p-type InAlAs electric field control layer, two layers of the n-type InAlAs buffer layer and the p-type InAlAs electric field control layer, two layers of the n-type InAlAs buffer layer and the InAlAs multiplication layer, or three layers of the n-type InAlAs buffer layer, the InAlAs multiplication layer, and the p-type InAlAs electric field control layer are composed of a digital alloy structure.

2. A semiconductor light-receiving device comprising:
a InP substrate;
a p-type InP cladding layer formed above the InP substrate an InGaAs light absorption layer formed above the p-type InP cladding layer;
a p-type InAlAs electric field control layer formed above the InGaAs light absorption layer;
an InAlAs multiplication layer formed above the p-type InAlAs selectric field control layer; and
an n-type InP cladding layer formed above the InAlAs multiplication layer; wherein
the InAlAs multiplication layer and the p-type InAlAs electric field control layer are composed of a digital alloy structure.

3. The semiconductor light-receiving device according to claim 1, wherein
in the case where the n-type InAlAs buffer layer is composed of the digital alloy structure, the n-type InAlAs buffer layer is composed of the digital alloy structure in which first buffer constituent layers having a thickness of R times (2≤R≤6) the thickness of the monolayer and second buffer constituent layers having a thickness of S times (2≤S≤6) the thickness of the monolayer with a bandgap energy smaller than that of the first buffer constituent layer are alternately stacked a plurality of times.

4. The semiconductor light-receiving device according to claim 1, further comprising:
a light-receiving section formed above the InP substrate and including at least the n-type InAlAs buffer layer, the InAlAs multiplication layer, the p-type InAlAs electric field control layer, and the InGaAs light absorption layer; and
an optical waveguide section formed above the InP substrate so as to be in contact with the light-receiving section and including at least an InGaAsP or InAlGaAs optical waveguide layer configured to guide incident light into the InGaAs light absorption layer.

5. The semiconductor light-receiving device according to claim 1, further comprising:
a light-receiving section formed above the InP substrate and including at least the n-type InAlAs buffer layer, the InAlAs multiplication layer, the p-type InAlAs electric field control layer, and the InGaAs light absorption layer; and
an optical waveguide section formed above the InP substrate so as to be in contact with the light-receiving section and including at least an InGaAsP or InAlGaAs optical waveguide layer configured to guide incident light into the n-type InAlAs buffer layer.

6. The semiconductor light-receiving device according to claim 2, further comprising:
an n-type InGaAsP or InAlGaAs optical waveguide layer formed between the InAlAs multiplication layer and the n-type InP cladding layer and having a refractive index higher than that of the InAlAs multiplication layer.

7. The semiconductor light-receiving device according to claim 2, further comprising:
a light-receiving section formed above the InP substrate and including at least the p-type InP cladding layer, the InGaAs light absorption layer, the p-type InAlAs electric field control layer, the InAlAs multiplication layer, and an n-type InP cladding layer; and
an optical waveguide section formed above the InP substrate so as to be in contact with the light-receiving section and including at least an as InGaAsP or InAlGaAs optical waveguide layer configured to guide incident light into the InGaAs light absorption layer.

8. The semiconductor light-receiving device according to claim 2, further comprising:
a light-receiving section formed above the InP substrate and including at least the p-type InP cladding layer, the InGaAs light absorption layer, the p-type InAlAs electric field control layer, the InAlAs multiplication layer, an n-type in InAlAs, InGaAsP or InAlGaAs optical waveguide layer, and an n-type InP cladding layer; and
an optical waveguide section formed above the InP substrate so as to be in contact with the light-receiving section and including at least an InGaAsP or InAlGaAs optical waveguide layer configured to guide incident light into the n-type InAlAs, InGaAsP or InAlGaAs optical waveguide layer.

9. The semiconductor light-receiving device according to claim 1, wherein
in the case where the InAlAs multiplication layer is composed of the digital alloy structure, the InAlAs multiplication layer is composed of the digital alloy structure in which first multiplication constituent layers having a thickness of M times (2≤M≤6) the thickness of the monolayer and second multiplication constituent layers having a thickness of N times (2≤N≤6) the thickness of the monolayer with a bandgap energy smaller than that of the first multiplication constituent layer are alternately stacked a plurality of times.

10. The semiconductor light-receiving device according to claim 1, wherein
in the case where the p-type InAlAs electric field control layer is composed of the digital alloy structure, the p-type InAlAs electric field control layer is composed of the digital alloy structure in which first electric field control constituent layers having a thickness of P times (2≤P≤6) the thickness of the monolayer and second electric field control constituent layers having a thickness of Q times (2≤Q≤6) the thickness of the monolayer with a bandgap energy smaller than that of the first electric field control constituent layer are alternately stacked a plurality of times.

11. The semiconductor light-receiving device according to claim 9, wherein
the first multiplication constituent layer is formed of an AlAs layer, and the second multiplication constituent layer is formed of an InAs layer.

12. The semiconductor light-receiving device according to claim 10, wherein
the first electric field control constituent layer is formed of an AlAs layer, and the second electric field control constituent layer is formed of an InAs layer.

13. The semiconductor light-receiving device according to claim 3, wherein
the first buffer constituent layer is formed of an AlAs layer, and the second buffer constituent layer is formed of an InAs layer.

14. A semiconductor light-receiving device comprising:
an InP substrate;
an InAlAs multiplication layer formed above the InP substrate, the InAlAs multiplication layer being composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute, value of the refractive index difference between the digital alloy structure and InP is zero or more and 0.02 or less in the wavelength band between 1200 nm and 1600 nm;
a p-type InAlAs electric field control layer formed above the InAlAs multiplication layer, the p-type InAlAs electric field control layer being composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm; and
an InGaAs light absorption layer formed above the p-type InAlAs electric field control layer.

15. The semiconductor light-receiving device according to claim 1, wherein
the semiconductor light-receiving device is a waveguide type APD configured to incident light from an end surface.

16. The semiconductor light-receiving device according to claim 1, wherein
the InAlAs multiplication layer is composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm.

17. The semiconductor light-receiving device according to claim 1, wherein
the p-type InAlAs electric field control layer is composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm.

18. A semiconductor light-receiving device comprising:
an InP substrate;
an n-type semiconductor layer formed above the InP substrate;
an InAlAs multiplication layer formed above the n-type semiconductor layer, the InAlAs multiplication layer being composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm;
a p-type InP electric field control layer formed above the InAlAs multiplication layer composed of the digital alloy structure; and
an InGaAs light absorption layer formed above the p-type InP electric field control layer.

19. A semiconductor light-receiving device comprising:
an InP substrate;
a p-type semiconductor layer formed above the InP substrate;
an InGaAs light absorption layer formed above the p-type semiconductor layer;
a p-type InP electric field control layer formed above the InGaAs light absorption layer;
an InAlAs multiplication layer formed above the p-type InP electric field control layer, the InAlAs multiplication layer being composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm; and
an n-type semiconductor layer formed above the InAlAs multiplication layer composed of the digital alloy structure.

20. The semiconductor light-receiving device according to claim 18, further comprising:
a light-receiving section formed above the InP substrate and including at least the n-type semiconductor layer, the InAlAs multiplication layer composed of the digital alloy structure, the p-type InP electric field control layer, and the InGaAs light absorption layer; and
an optical waveguide section formed above the InP substrate so as to be in contact with the light-receiving section and including at least an InGaAsP or InAlGaAs optical waveguide layer configured to guide incident light into the InGaAs light absorption layer.

21. The semiconductor light-receiving device according to claim 18, further comprising:
a light-receiving section formed above the InP substrate and including at least the n-type semiconductor layer, the InAlAs multiplication layer composed of the digital alloy structure, the p-type InP electric field control layer, and the InGaAs light absorption layer; and
an optical waveguide section formed above the InP substrate so as to be in contact with the light-receiving section and including at least an InGaAsP or InAlGaAs optical waveguide layer configured to guide incident light into the n-type semiconductor layer.

22. The semiconductor light-receiving device according to claim 19, further comprising:
an n-type InGaAsP or InAlGaAs optical waveguide layer formed between the InAlAs multiplication layer composed of the digital alloy structure and the n-type semiconductor layer and having a refractive index higher than that of the InAlAs multiplication layer composed of the digital alloy structure.

23. The semiconductor light-receiving device according to claim 19, further comprising:
a light-receiving section formed above the InP substrate and including at least the p-type semiconductor layer, the InGaAs light absorption layer, the p-type InP electric field control layer, the InAlAs multiplication layer composed of the digital alloy structure, and the n-type semiconductor layer; and
an optical waveguide section formed above the InP substrate so as to be in contact with the light-receiving section and including at least an InGaAsP or InAlGaAs optical waveguide layer configured to guide incident light into the InGaAs light absorption layer.

24. The semiconductor light-receiving device according to claim 19, further comprising:
a light-receiving section formed above the InP substrate and including at least the p-type semiconductor layer, the InGaAs light absorption layer, the p-type InP electric field control layer, the InAlAs multiplication layer composed of the digital alloy structure, an n-type InAlAs, InGaAsP or InAlGaAs optical waveguide layer, and the n-type semiconductor layer; and
an optical waveguide section formed above the InP substrate so as to be in contact with the light-receiving section and including at least an InGaAsP or InAlGaAs optical waveguide layer configured to guide incident light into the n-type InAlAs, InGaAsP or InAlGaAs optical waveguide layer.

25. A semiconductor light-receiving device comprising:
an InP substrate;
an InAlAs multiplication layer formed above the InP substrate, the InAlAs multiplication layer being composed of a digital alloy structure including AlAs layers having a thickness of M times (2≤M≤6) the thickness of the monolayer and InAs layers having a thickness of N times (2≤N≤6) the thickness of the monolayer, the AlAs layers and the InAs layers being alternately stacked a plurality of times in the digital alloy structure, the absolute value of the refractive index difference between the digital alloy structure and InP is zero or more and 0.02 or less in the wavelength band between 1200 nm and 1600 nm;
a p-type InP electric field control layer formed above the InAlAs multiplication layer composed of the digital alloy structure; and
an InGaAs light absorption layer formed above the p-type InP electric field control layer.

26. The semiconductor light-receiving device according to claim 18, wherein
the semiconductor light-receiving device is a waveguide type APD configured to incident light from an end surface.
